(19) United States
(12) Patent Application Publication
(10) Pub. No.: US 2026/0271529 A1
(43) Pub. Date: Sep. 10, 2026

(54) DISPLAY DEVICE

(71) Applicant: Sharp Display Technology Corporation, Kameyama City, Mie (JP)

(72) Inventors: Hiroyuki MADONO, Kameyama City, Mie (JP); Takeshi HIRASE, Kameyama City, Mie (JP); Takashi TOYODA, Kameyama City, Mie (JP)

(21) Appl. No.: 19/125,565

(22) PCT Filed: Nov. 14, 2022
(86) PCT No.: PCT/JP2022/042290

§ 371 Date: Apr. 29, 2025

(51) Int. Cl. H10K 59/122; H10K 59/80

(52) U.S. Cl. CPC H10K 59/122; H10K 59/873

(57) ABSTRACT

A non-display area of a display area has a through hole running through a display panel in its thickness direction and includes a plurality of annular banks provided so as to surround the through hole. Each of the plurality of banks includes a resin portion divided by a plurality of slits each formed annularly on the surface of a resin substrate layer that faces a TFT layer, so as to surround the through hole. The center of gravity of the through hole in a plan view is located so as to be displaced in a direction further away from a panel edge than the center of gravity of the slit in a plan view is displaced in that direction away from the panel edge, the slit being the outermost slit in the plurality of slits.

### TECHNICAL FIELD

The disclosure relates to display devices.

### BACKGROUND ART

The organic EL display device, or the self-luminous display device built around organic electroluminescence (hereinafter, may be referred to as “EL”) elements, has been attracting attention as an alternative to the liquid crystal display device. The organic EL display device includes an organic EL display panel that in turn includes, for example: a resin substrate layer; a TFT layer provided on the resin substrate layer and carrying thereon thin film transistors (hereinafter, may be referred to as “TFTs”); an organic EL element layer provided on the TFT layer and carrying thereon organic EL elements; and an encapsulation film provided on the organic EL element layer. For the organic EL display device including such an organic EL display panel, structures are proposed in which there are provided: an insular non-display area inside a display area for producing an image display to accommodate therein, for example, a camera, a fingerprint sensor, or another electronic component; and a through hole that runs through the non-display area in its thickness direction.

For instance, Patent Literature 1 discloses an organic EL panel in which there are provided: a through hole constituting at least a part of a camera hole inside the display area; an annular inclined partition enclosing the through hole; a common electrode, constituting at least a part of a light-emitting element, that is broken up by the inclined partition; and an inorganic encapsulation film sealing the ends of the common electrode.

### CITATION LIST

### Patent Literature

Patent Literature 1: Japanese Unexamined Patent Application Publication No. 2022-72381

### SUMMARY

### Technical Problem

Meanwhile, self-luminous elements such as organic EL elements include: for example, a first electrode provided on a TFT layer; a light-emitting functional layer provided on the first electrode; and a second electrode provided on the light-emitting functional layer. Here, the light-emitting functional layer includes: a plurality of individual light-emitting functional layers provided so as to correspond to a plurality of subpixels inside the display area; and a common light-emitting functional layer provided commonly to these plurality of subpixels. Note that the second electrode is provided commonly to the plurality of subpixels similarly to the common light-emitting functional layer. Then, in a self-luminous display device including the above-described self-luminous element provided with a through hole inside the display area, for example, moisture and like water content can penetrate through, for example, the common light-emitting functional layer and/or the second electrode that are exposed in the through hole, which may degrade the common light-emitting functional layer and the individual light-emitting functional layers that are in contact with the common light-emitting functional layer. For this reason, the common light-emitting functional layer and the second electrode need to be formed divided for a display area side and for a through hole side around the through hole. Accordingly, for the self-luminous display device, it is proposed to form a plurality of banks by patterning an inorganic insulating film constituting at least a part of the TFT layer and then forming an annular slit in a resin substrate layer around the through hole by utilizing the patterned inorganic insulating film. With these plurality of banks made of the resin substrate layer and the inorganic insulating film, the common light-emitting functional layer and the second electrode can indeed be formed divided for the display area side and for the through hole side. Nevertheless, the distance between the through hole and the panel edge tends to be short in self-luminous display devices where there is an increasing demand to reduce the width of the frame area surrounding the display area. Under these circumstances, in the self-luminous display device including the plurality of banks made of the resin substrate layer and the inorganic insulating film, the resin substrate layer is exposed on the edge face of the through hole and the edge face of the panel edge, which are positioned close to each other, thereby allowing moisture and like water content to penetrate into the resin substrate layer from both sides of the edge face of the through hole and the edge face of the panel edge. That can in turn accelerate degradation of the light-emitting functional layer on the panel edge side of the through hole, which should be addressed.

The disclosure has been made in view of these problems and has an object to restrain degradation of the light-emitting functional layer on the panel edge side of the through hole in a display device including a plurality of banks that use a resin substrate layer around the through hole.

### Solution to Problem

To achieve the object, a display device includes a display panel including: a resin substrate layer; a thin film transistor layer provided on the resin substrate layer and including an inorganic insulating film; a light-emitting element layer provided on the thin film transistor layer and including a plurality of first electrodes, a light-emitting functional layer, and a second electrode stacked sequentially correspondingly to a plurality of subpixels inside a display area; and a first inorganic encapsulation film provided on the light-emitting element layer, wherein a non-display area is provided insularly inside the display area along a panel edge of the display panel, a through hole running through the display panel in a thickness direction thereof is provided in the non-display area, a plurality of banks are provided annularly in the non-display area so as to surround the through hole, each of the plurality of banks includes: a resin portion formed of a part of the resin substrate layer; and an inorganic insulating layer provided on the resin portion and made of a same material, and provided in a same layer, as the inorganic insulating film, the resin portion of each of the plurality of banks is divided by a plurality of slits each formed annularly on a surface of the resin substrate layer that faces the thin film transistor layer, so as to surround the through hole, and the first inorganic encapsulation film is provided so as to cover the plurality of banks and the plurality of slits, wherein the through hole has, in a plan view, a center of gravity that is located so as to be displaced in a direction further away from the panel edge than a center of gravity of one of the plurality of slits in a plan view is displaced in that direction away from the panel edge, the one of the plurality of slits being an outermost slit in the plurality of slits.

### Advantageous Effects

The disclosure can restrain degradation of the light-emitting functional layer on the panel edge side of the through hole in a display device including a plurality of banks that use a resin substrate layer around the through hole.

### BRIEF DESCRIPTION OF DRAWINGS

FIG. 1 is a schematic plan view of a structure of an organic EL display device in accordance with a first embodiment of the disclosure.

FIG. 2 is a plan view of a display area of an organic EL display panel that is a part of the organic EL display device in accordance with the first embodiment of the disclosure.

FIG. 3 is a cross-sectional view of the display area of the organic EL display panel, taken along line III-III shown in FIG. 1.

FIG. 4 is an equivalent circuit diagram of a TFT layer that is a part of the organic EL display panel in accordance with the first embodiment of the disclosure.

FIG. 5 is a cross-sectional view of an organic EL layer that is a part of the organic EL display panel in accordance with the first embodiment of the disclosure.

FIG. 6 is a plan view of a non-display area and its surrounding portion of the organic EL display panel in accordance with the first embodiment of the disclosure.

FIG. 7 is a cross-sectional view of the non-display area of the organic EL display panel, taken along line VII-VII shown in FIG. 6.

FIG. 8 is a cross-sectional view of the non-display area of the organic EL display panel, taken along line VIII-VIII shown in FIG. 6.

FIG. 9 is a cross-sectional view of the organic EL display panel, taken along line IX-IX shown in FIG. 1.

FIG. 10 is a plan view of a non-display area and its surrounding portion of a first variation example of the organic EL display panel in accordance with the first embodiment of the disclosure and corresponds to FIG. 6.

FIG. 11 is a plan view of a non-display area and its surrounding portion of a second variation example of the organic EL display panel in accordance with the first embodiment of the disclosure and corresponds to FIG. 6.

FIG. 12 is a plan view of a non-display area and its surrounding portion of a third variation example of the organic EL display panel in accordance with the first embodiment of the disclosure and corresponds to FIG. 6.

FIG. 13 is a plan view of a non-display area and its surrounding portion of a fourth variation example of the organic EL display panel in accordance with the first embodiment of the disclosure and corresponds to FIG. 6.

FIG. 14 is a plan view of a non-display area and its surrounding portion of a fifth variation example of the organic EL display panel in accordance with the first embodiment of the disclosure and corresponds to FIG. 6.

FIG. 15 is a cross-sectional view of a non-display area of an organic EL display panel in that is a part of an organic EL display device in accordance with a second embodiment of the disclosure and corresponds to FIG. 8.

FIG. 16 is a cross-sectional view of a non-display area of an organic EL display panel that is a part of an organic EL display device in accordance with a third embodiment of the disclosure and corresponds to FIG. 8.

FIG. 17 is a cross-sectional view of a non-display area of an organic EL display panel that is a part of an organic EL display device in accordance with a fourth embodiment of the disclosure and corresponds to FIG. 8.

FIG. 18 is a cross-sectional view of a non-display area of an organic EL display panel that is a part of an organic EL display device in accordance with a fifth embodiment of the disclosure and corresponds to FIG. 8.

### DESCRIPTION OF EMBODIMENTS

The following will describe embodiments of the disclosure in detail with reference to drawings. Note that the disclosure is not limited to these embodiments.

### First Embodiment

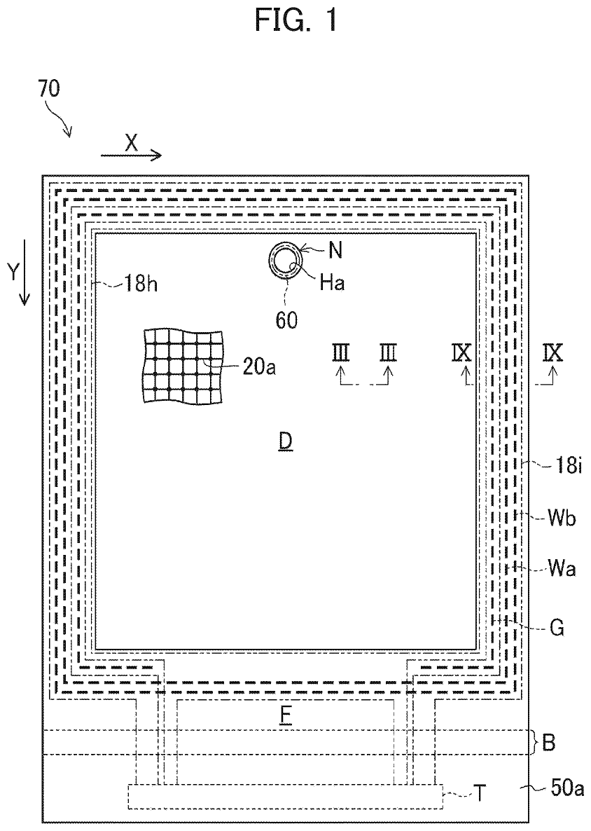

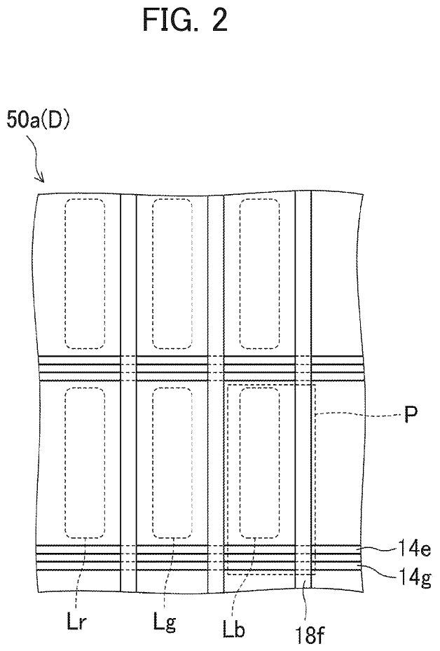

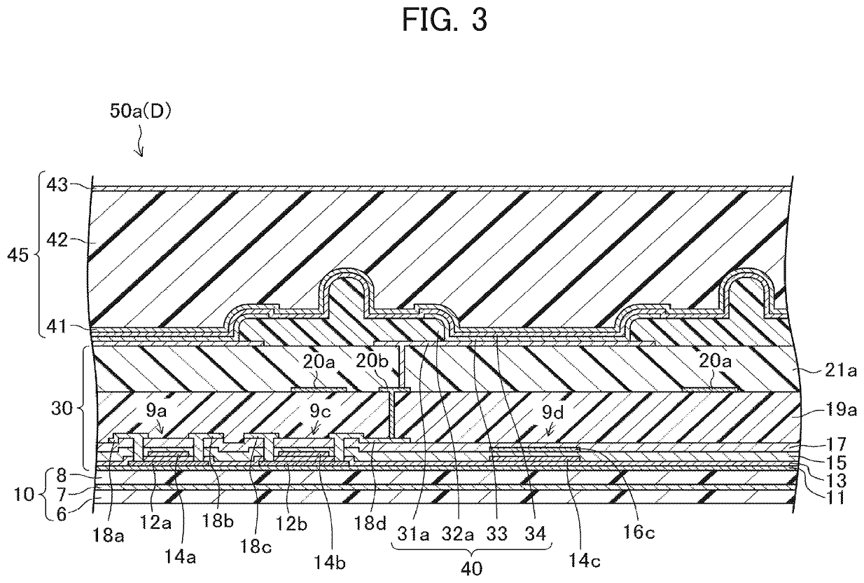

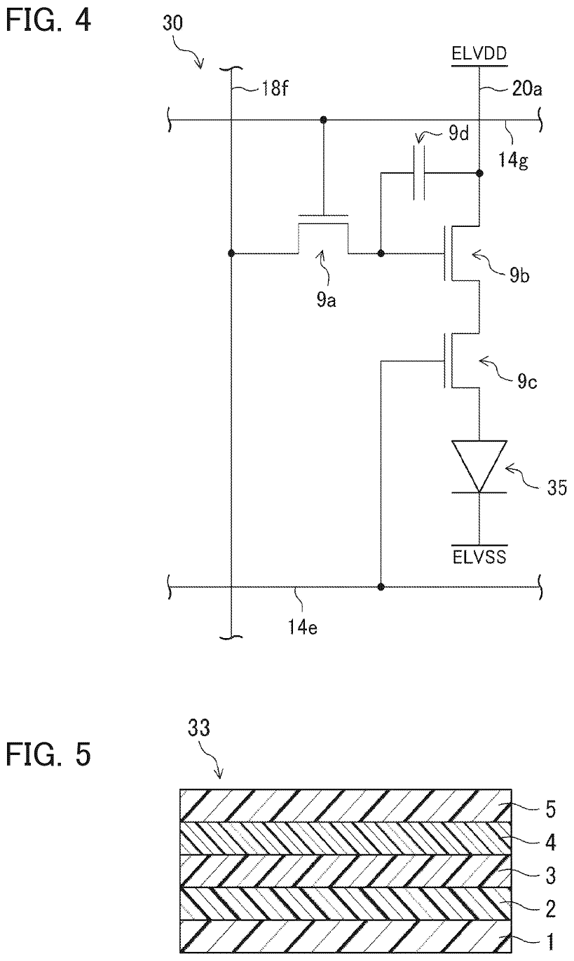

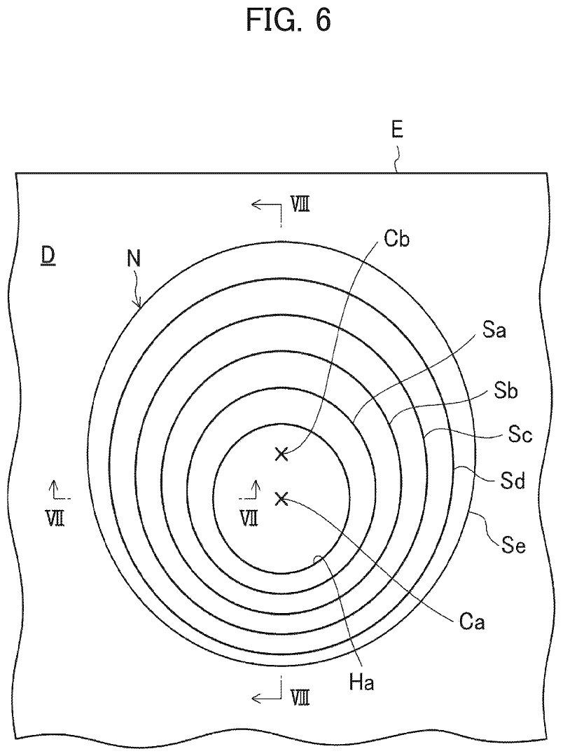

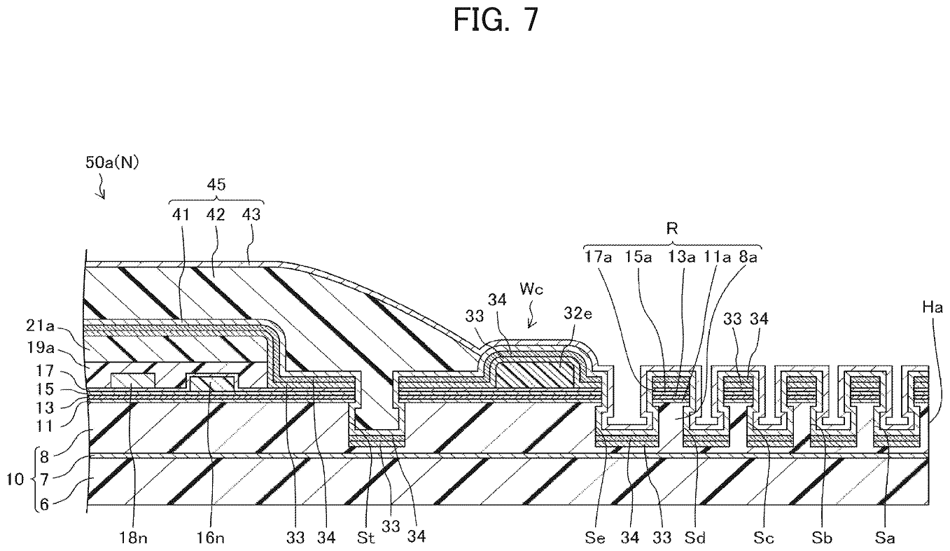

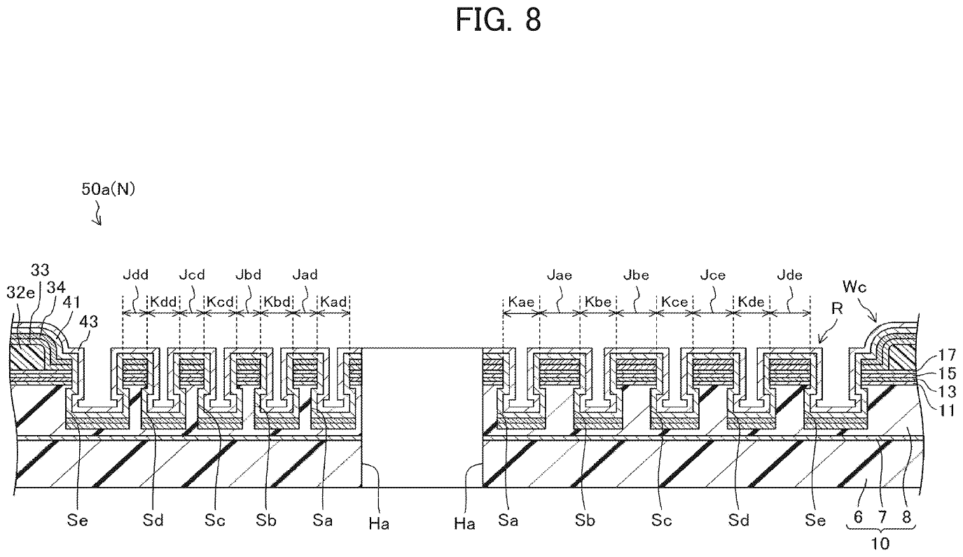

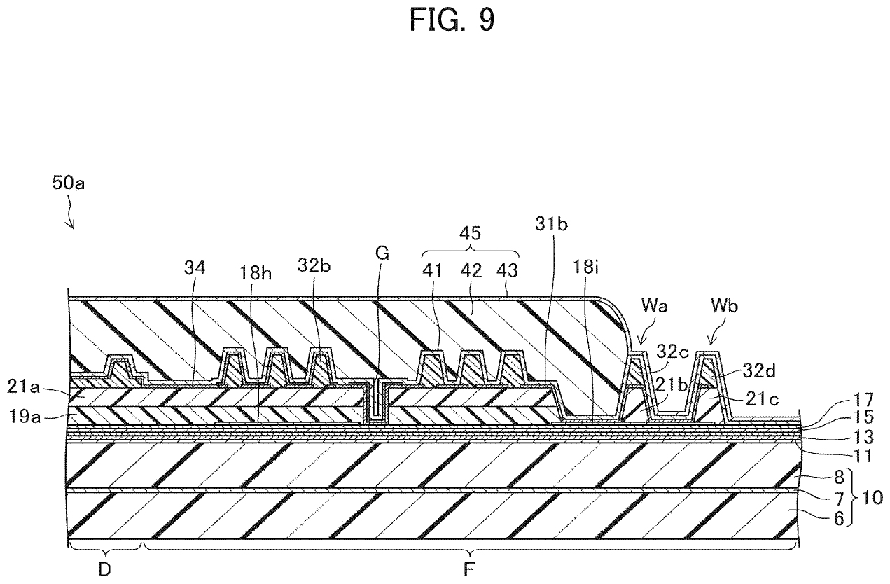

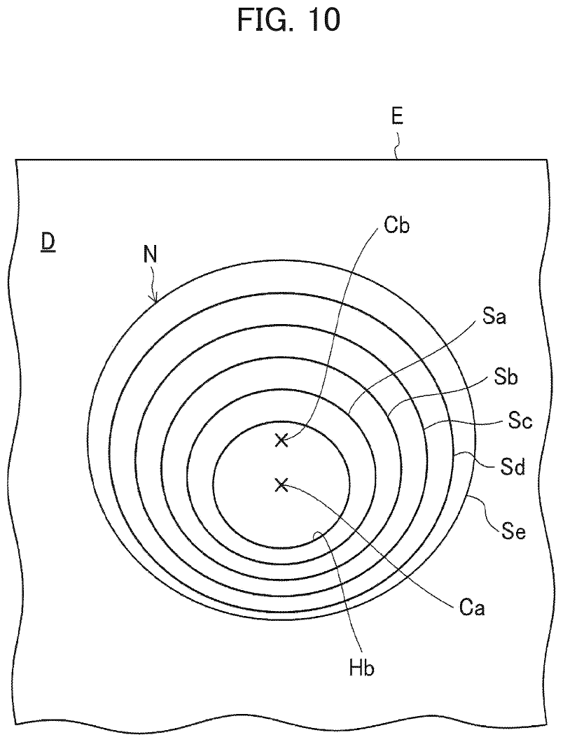

FIGS. 1 to 8 illustrate a first embodiment of the display device in accordance with the disclosure. Note that the following embodiments discuss organic EL display devices including organic EL elements as an example of the display device including light-emitting elements. Here, FIG. 1 is a schematic plan view of a structure of an organic EL display device 70 in accordance with the present embodiment. In addition, FIG. 2 is a plan view of a display area D of an organic EL display panel 50a that is a part of the organic EL display device 70. In addition, FIG. 3 is a cross-sectional view of the display area of the organic EL display panel 50a, taken along line III-III shown in FIG. 1. In addition, FIG. 4 is an equivalent circuit diagram of a TFT layer 30 that is a part of the organic EL display panel 50a. In addition, FIG. 5 is a cross-sectional view of an organic EL layer 33 that is a part of the organic EL display panel 50a. In addition, FIG. 6 is a plan view of a non-display area N and its surrounding portion of the organic EL display panel 50a. In addition, FIG. 7 is a cross-sectional view of the non-display area N of the organic EL display panel 50a, taken along line VII-VII shown in FIG. 6. In addition, FIG. 8 is a cross-sectional view of the non-display area N of the organic EL display panel 50a, taken along line VIII-VIII shown in FIG. 6. In addition, FIG. 9 is a cross-sectional view of the organic EL display panel 50a, taken along line IX-IX shown in FIG. 1. In addition, FIGS. 10, 11, 12, 13, and 14 are plan views of a non-display area and its surrounding portion in a first variation example, a second variation example, a third variation example, a fourth variation example, and a fifth variation example of the organic EL display panel 50a respectively and correspond to FIG. 6.

Referring to FIG. 1, the organic EL display device 70 includes: the organic EL display panel 50a with a through hole Ha in the non-display area N; and an image sensor 60 disposed, as an electronic component, on the backside of the through hole Ha of the organic EL display panel 50a, as will be described later in detail.

Referring to FIG. 1, the organic EL display panel 50a has, for example: the rectangular display area D for producing an image display; and a frame-shaped frame area F surrounding the display area D. Note that although the present embodiment discusses the rectangular display area D as an example, this rectangular shape may encompass, for example, generally rectangular shapes such as shapes with a curved side(s), shapes with a round corner(s) and shapes with a notched side(s).

Referring to FIG. 2, there is provided a matrix of subpixels P in the display area D. In addition, referring to FIG. 2, in the display area D, there are provided, for example, subpixels P each including a red-light-emission region Lr for producing a red display, subpixels P each including a green-light-emission region Lg for producing a green display, and subpixels P each including a blue-light-emission region Lb for producing a blue display, so as to be adjacent to each other. Note that as an example, in the display area D, one pixel is formed by three adjacent subpixels P including one of the red-light-emission regions Lr, one of the green-light-emission regions Lg, and one of the blue-light-emission regions Lb. In addition, referring to FIG. 1, inside the display area D, the non-display area N is provided insularly along a panel edge E of the organic EL display panel 50a. Here, in the non-display area N, the through hole Ha, which runs through the organic EL display panel 50a in its thickness direction, is provided circularly in a plan view as shown in FIG. 1, to allow installing the image sensor 60 on the backside.

In the bottom portion of the frame area F in FIG. 1, there is provided a terminal section T extending in one direction (X-direction in the drawing). Here, in the frame area F, as shown in FIG. 1, a bending portion B that is bendable, for example, into 180° (a U-shape) about a bending axis, which is the X-direction in the drawing, is provided between the display area D and the terminal section T so as to extend in one direction (X-direction in the drawing). In addition, in the frame area F, in a first planarization film 19a and a second planarization film 21a, which will be described later in detail, as shown in FIGS. 1 and 9, there is provided a trench G that is shaped generally like a letter “C” in a plan view so as to run through the first planarization film 19a and the second planarization film 21a. Here, the trench G is shaped generally like a letter “C” so as to open on the terminal section T side in a plan view as shown in FIG. 1.

Referring to FIG. 3, the organic EL display panel 50a includes: a resin substrate layer 10; the TFT layer 30 provided on the resin substrate layer 10; an organic EL element layer 40 provided as a light-emitting element layer on the TFT layer 30; and an encapsulation film 45 provided on the organic EL element layer 40.

Referring to FIGS. 3, 7, 8, and 9, the resin substrate layer 10 includes: a first resin substrate layer 6 provided opposite the TFT layer 30; a second resin substrate layer 8 provided on the TFT layer 30 side; and an intra-substrate inorganic insulating film 7 provided between the first resin substrate layer 6 and the second resin substrate layer 8. Here, the first resin substrate layer 6 and the second resin substrate layer 8 are made of, for example, a polyimide resin. In addition, the intra-substrate inorganic insulating film 7 and a base coat film 11, a gate insulating film 13, a first interlayer insulating film 15, and a second interlayer insulating film 17 that will be described later in detail each either include, for example, a monolayer film of an inorganic insulating material such as silicon nitride, silicon oxide, or silicon oxynitride or include a stack of such films.

Referring to FIG. 3, the TFT layer 30 includes: the base coat film 11 provided on the resin substrate layer 10; a plurality of first TFTs 9a, a plurality of second TFTs 9b (see FIG. 4), a plurality of third TFTs 9c, and a plurality of capacitors 9d, all of which are provided on the base coat film 11; and the first planarization film 19a and the second planarization film 21a, which are provided sequentially on each of the first TFTs 9a, each of the second TFTs 9b, each of the third TFTs 9c, and each of the capacitors 9d. In addition, referring to FIG. 3, the TFT layer 30 includes the base coat film 11, a semiconductor film that will form, for example, a semiconductor layer 12a (detailed later), the gate insulating film 13, a first metal film that will form, for example, gate lines 14g (detailed later), the first interlayer insulating film 15, a second metal film that will form, for example, an overlying conductive layer 16c (detailed later), the second interlayer insulating film 17, a third metal film that will form, for example, source lines 18f (detailed later), the first planarization film 19a, a fourth metal film that will form, for example, power supply lines 20a, and the second planarization film 21a, which are stacked sequentially on the resin substrate layer 10. Note that the base coat film 11, the gate insulating film 13, the first interlayer insulating film 15, and the second interlayer insulating film 17 are provided as inorganic insulating films that are a part of the TFT layer 30 as described above.

In the TFT layer 30, the plurality of gate lines 14g are provided so as to extend parallel to each other in the lateral direction in the drawing, as shown in FIG. 2. In addition, in the TFT layer 30, there is provided a plurality of light-emission control lines 14e so as to extend parallel to each other in the lateral direction in the drawing, as shown in FIG. 2. Note that each light-emission control line 14e is provided adjacent to each gate line 14g as shown in FIG. 2. In addition, in the TFT layer 30, the plurality of source lines 18f are provided so as to extend parallel to each other in the vertical direction in the drawing, as shown in FIG. 2. In addition, in the TFT layer 30, the power supply lines 20a are provided like a lattice between, the first planarization film 19a and the second planarization film 21a as shown in FIGS. 1 and 3. In addition, in the TFT layer 30, one of the first TFTs 9a, one of the second TFTs 9b, one of the third TFTs 9c, and one of the capacitors 9d are provided in each subpixel P as shown in FIG. 4.

Referring to FIG. 4, the first TFT 9a in each subpixel P is electrically connected to a corresponding one of the gate lines 14g, a corresponding one of the source lines 18f, and a corresponding one of the second TFTs 9b. In addition, referring to FIG. 3, each first TFT 9a includes the semiconductor layer 12a, the gate insulating film 13, a gate electrode 14a, the first interlayer insulating film 15, the second interlayer insulating film 17, and a source electrode 18a and a drain electrode 18b, which are provided sequentially on the base coat film 11. Here, referring to FIG. 3, the semiconductor layer 12a is provided insularly on the base coat film 11 and includes a channel region, a source region, and a drain region. In addition, referring to FIG. 3, the gate insulating film 13 is provided so as to cover the semiconductor layer 12a. In addition, referring to FIG. 3, the gate electrode 14a is provided on the gate insulating film 13 so as to overlap the channel region of the semiconductor layer 12a. In addition, referring to FIG. 3, the first interlayer insulating film 15 and the second interlayer insulating film 17 are provided sequentially so as to cover the gate electrode 14a. In addition, referring to FIG. 3, the source electrode 18a and the drain electrode 18b are provided on the second interlayer insulating film 17 so as to be separated from each other. In addition, referring to FIG. 3, the source electrode 18a and the drain electrode 18b are electrically connected respectively to the source region and the drain region of the semiconductor layer 12a via the contact holes formed through a stack of the gate insulating film 13, the first interlayer insulating film 15, and the second interlayer insulating film 17.

Referring to FIG. 4, the second TFT 9b in each subpixel Pis electrically connected to a corresponding one of the first TFTs 9a, a corresponding one of the power supply lines 20a, and a corresponding one of the third TFTs 9c. Note that the second TFTs 9b have substantially the same structure as the first TFTs 9a and the third TFTs 9c (detailed later).

Referring to FIG. 4, the third TFT 9c in each subpixel P is electrically connected to a corresponding one of the second TFTs 9b, a corresponding one of first electrodes 31a of organic EL elements 35 (detailed later), and a corresponding one of the light-emission control lines 14e. In addition, referring to FIG. 3, the third TFT 9c includes a semiconductor layer 12b, the gate insulating film 13, a gate electrode 14b, the first interlayer insulating film 15, the second interlayer insulating film 17, and a source electrode 18c and a drain electrode 18d, which are provided sequentially on the base coat film 11. Here, referring to FIG. 3, the semiconductor layer 12b is provided insularly on the base coat film 11 and includes a channel region, a source region, and a drain region similarly to the foregoing semiconductor layer 12a. In addition, referring to FIG. 3, the gate insulating film 13 is provided so as to cover the semiconductor layer 12b. In addition, referring to FIG. 3, the gate electrode 14b is provided on the gate insulating film 13 so as to overlap the channel region of the semiconductor layer 12b. In addition, referring to FIG. 3, the first interlayer insulating film 15 and the second interlayer insulating film 17 are provided sequentially so as to cover the gate electrode 14b. In addition, referring to FIG. 3, the source electrode 18c and the drain electrode 18d are provided on the second interlayer insulating film 17 so as to be separated from each other. In addition, referring to FIG. 3, the source electrode 18c and the drain electrode 18d are electrically connected respectively to the source region and the drain region of the semiconductor layer 12b via the contact holes formed through the stack of the gate insulating film 13, the first interlayer insulating film 15, and the second interlayer insulating film 17.

Note that the present embodiment discusses an example where the first TFTs 9a, the second TFTs 9b, and the third TFTs 9c all have a top gate structure. Alternatively, the first TFTs 9a, the second TFTs 9b, and the third TFTs 9c may have a bottom gate structure.

Referring to FIG. 4, the capacitor 9d in each subpixel P is electrically connected to a corresponding one of the first TFTs 9a and a corresponding one of the power supply lines 20a. Here, referring to FIG. 3, the capacitor 9d includes: an underlying conductive layer 14c formed of the first metal film; the first interlayer insulating film 15 provided so as to cover the underlying conductive layer 14c; and the overlying conductive layer 16c formed of the second metal film on the first interlayer insulating film 15 so as to overlap the underlying conductive layer 14c. Note that the overlying conductive layer 16c is electrically connected to the power supply lines 20a via contact holes (not shown) formed in the second interlayer insulating film 17 and the first planarization film 19a.

The first planarization film 19a and the second planarization film 21a have a flat surface inside the display area D and are made of, for example, either an organic resin material such as a polyimide resin or an acrylic resin or a polysiloxane-based SOG (spin on glass) material. Here, referring to FIG. 3, a relay electrode 20b, apart from the above-described power supply lines 20a, is formed of the fourth metal film between the first planarization film 19a and the second planarization film 21a.

Referring to FIG. 3, the organic EL element layer 40 includes the plurality of first electrodes 31a, an edge cover 32a, the organic EL layer 33, and a second electrode 34, which are stacked sequentially on the TFT layer 30. Here, the organic EL element 35 includes one of the plurality of first electrodes 31a, the organic EL layer 33, and the second electrode 34, which are stacked sequentially on the TFT layer 30.

Referring to FIG. 3, the plurality of first electrodes 31a are provided in a matrix on the second planarization film 21a so as to correspond to the plurality of subpixels P. Here, referring to FIG. 3, the first electrode 31a is electrically connected to the drain electrode 18d of a corresponding one of the third TFTs 9c via a contact hole formed in the first planarization film 19a, the relay electrode 20b, and a contact hole formed in the second planarization film 21a. In addition, the first electrode 31a has a function of injecting holes to the organic EL layer 33. In addition, the first electrode 31a is more preferably made of a material that has a high work function, to improve the efficiency of hole injection to the organic EL layer 33. Here, examples of the materials for the first electrodes 31a include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Alternatively, the first electrodes 31a may be made of, for example, an alloy such as an astatine-astatine oxide (At—AtO₂) alloy. As another alternative, the first electrodes 31a may be made of, for example, an electrically conductive oxide such as tin oxide (SnO), zinc oxide (ZnO), indium tin oxide (ITO), or indium zinc oxide (IZO). In addition, the first electrodes 31a may be formed of a stack of a plurality of layers each made of one of these materials. Note that examples of the compound materials that have a high work function include indium tin oxide (ITO) and indium zinc oxide (IZO).

The edge cover 32a is provided like a lattice so as to cover the peripheral portion of each first electrode 31a as shown in FIG. 3. Here, the edge cover 32a is made of, for example, either an organic resin material such as a polyimide resin or an acrylic resin or a polysiloxane-based SOG material.

Referring to FIG. 3, the organic EL layer 33 includes: individual light-emitting functional layers provided in a matrix so as to correspond to the plurality of subpixels P, so that one of the individual light-emitting functional layers is positioned on each first electrode 31a; and a common light-emitting functional layer provided commonly to the plurality of subpixels P. Here, referring to FIG. 5, the organic EL layer 33 includes a hole injection layer 1, a hole transport layer 2, an organic light-emitting layer 3, an electron transport layer 4, and an electron injection layer 5, which are provided sequentially on the first electrodes 31a. Note that the present embodiment discusses, as an example, the organic EL layer 33 including the organic light-emitting layer 3 as the individual light-emitting functional layers and including the hole injection layer 1, the hole transport layer 2, the electron transport layer 4, and the electron injection layer 5 as the common light-emitting functional layer. Alternatively, the organic light-emitting layer 3 may be the common light-emitting functional layer by performing color conversion by, for example, QLEDs (quantum-dot light-emitting diodes), and at least one of the hole injection layer 1, the hole transport layer 2, the electron transport layer 4, and the electron injection layer 5 may be the individual light-emitting functional layers.

The hole injection layer 1 is alternatively referred to as the anode buffer layer, has a function of bringing the energy levels of the first electrodes 31a and the organic EL layer 33 closer to each other to improve the efficiency of hole injection from the first electrodes 31a to the organic EL layer 33, and is provided as a common light-emitting functional layer that is common to the plurality of subpixels P. Here, examples of the materials for the hole injection layer 1 include triazole derivatives, oxadiazole derivatives, imidazole derivatives, polyaryl alkane derivatives, pyrazoline derivatives, phenylenediamine derivatives, oxazole derivatives, styryl anthracene derivatives, fluorenone derivatives, hydrazone derivatives, and stilbene derivatives.

The hole transport layer 2 has a function of improving the efficiency of hole transport from the first electrodes 31a to the organic EL layer 33 and is provided as a common light-emitting functional layer that is common to the plurality of subpixels P. Here, examples of the materials for the hole transport layer 2 include porphyrin derivatives, aromatic tertiary amine compounds, styryl amine derivatives, polyvinyl carbazole, poly-p-phenylene vinylene, polysilane, triazole derivatives, oxadiazole derivatives, imidazole derivatives, polyaryl alkane derivatives, pyrazoline derivatives, pyrazolone derivatives, phenylenediamine derivatives, aryl amine derivatives, amine-substituted chalcone derivatives, oxazole derivatives, styryl anthracene derivatives, fluorenone derivatives, hydrazone derivatives, stilbene derivatives, hydrogenated amorphous silicon, hydrogenated amorphous silicon carbide, zinc sulfide, and zinc selenide.

The organic light-emitting layer 3 is a region where holes and electrons are injected from the first electrodes 31a and the second electrode 34 respectively under a voltage applied by the first electrodes 31a and the second electrode 34 so that holes and electrons can recombine and is provided as individual light-emitting functional layers so as to correspond to the plurality of subpixels P. Here, the organic light-emitting layer 3 is made of a material that has a high luminous efficiency. Then, examples of the materials for the organic light-emitting layer 3 include metal oxinoid compounds [8-hydroxy quinoline metal complex], naphthalene derivatives, anthracene derivatives, diphenyl ethylene derivatives, vinyl acetone derivatives, triphenyl amine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styryl amine derivatives, bis(styryl)benzene derivatives, tris(styryl)benzene derivatives, perylene derivatives, perynone derivatives, amino pyrene derivatives, pyridine derivatives, rhodamine derivatives, acridine derivatives, phenoxazone, quinacridone derivatives, rubrene, poly-p-phenylene vinylene, and polysilane.

The electron transport layer 4 has a function of efficiently moving electrons to the organic light-emitting layer 3 and is provided as a common light-emitting functional layer that is common to the plurality of subpixels P. Here, examples of the materials for the electron transport layer 4 include organic compounds such as oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 has a function of bringing the energy levels of the second electrode 34 and the organic EL layer 33 closer to each other to improve the efficiency of electron injection from the second electrode 34 to the organic EL layer 33 and owing to this function, is capable of lowering the drive voltage of the organic EL elements 35. Note that the electron injection layer 5 is alternatively referred to as the cathode buffer layer and is provided as a common light-emitting functional layer that is common to the plurality of subpixels P. Here, examples of the materials for the electron injection layer 5 include inorganic alkali compounds such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

The second electrode 34 is provided on the plurality of organic EL layers 33 so as to be common to the plurality of subpixels P, in other words, so as to cover each organic EL layer 33 and the edge cover 32a, as shown in FIG. 3. In addition, the second electrode 34 has a function of injecting electrons to the organic EL layer 33. In addition, the second electrode 34 is preferably made of a material that has a low work function to improve the efficiency of electron injection to the organic EL layer 33. Here, examples of the materials for the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Alternatively, the second electrode 34 may be made of an alloy such as a magnesium-copper (Mg—Cu) alloy, a magnesium-silver (Mg—Ag) alloy, a sodium-potassium (Na—K) alloy, an astatine-astatine oxide (At—AtO₂) alloy, a lithium-aluminum (Li—Al) alloy, a lithium-calcium-aluminum (Li—Ca—Al) alloy, or a lithium fluoride-calcium-aluminum (LiF—Ca—Al) alloy. Alternatively, the second electrode 34 may be made of an electrically conductive oxide such as tin oxide (SnO), zinc oxide (ZnO), indium tin oxide (ITO), or indium zinc oxide (IZO). Alternatively, the second electrode 34 may be formed of a stack of a plurality of layers each made of one of these materials. Note that examples of the materials that have a low work function include magnesium (Mg), lithium (Li), lithium fluoride (LiF), magnesium-copper (Mg—Cu) alloys, magnesium-silver (Mg—Ag) alloys, sodium-potassium (Na—K) alloys, lithium-aluminum (Li—Al) alloys, lithium-calcium-aluminum (Li—Ca—Al) alloys, and lithium fluoride-calcium-aluminum (LiF—Ca—Al) alloys.

The encapsulation film 45 is provided so as to cover the second electrode 34 as shown in FIG. 3, includes a first inorganic encapsulation film 41, an organic encapsulation film 42, and a second inorganic encapsulation film 43, which are stacked sequentially on the second electrode 34, and has a function of protecting the organic EL layer 33 in the organic EL elements 35 from, for example, moisture and like water content and oxygen. Here, the first inorganic encapsulation film 41 and the second inorganic encapsulation film 43 are formed of, for example, an inorganic insulating film such as a silicon nitride film, a silicon oxide film, or a silicon oxynitride film. In addition, the organic encapsulation film 42 is made of, for example, an organic resin material such as an acrylic resin, an epoxy resin, a silicone resin, a polyurea resin, a parylene resin, a polyimide resin, or a polyamide resin. Note that the present embodiment discusses, as an example, the encapsulation film 45 that has a three-layered structure in which the first inorganic encapsulation film 41, the organic encapsulation film 42, and the second inorganic encapsulation film 43 are stacked sequentially. Alternatively, the encapsulation film 45 may have, for example, a monolayer structure in which only the first inorganic encapsulation film 41 is provided or a two-layered structure in which the first inorganic encapsulation film 41 and the organic encapsulation film 42 are sequentially stacked. In addition, referring to FIGS. 7 and 9, in the encapsulation film 45, the organic encapsulation film 42 and the second inorganic encapsulation film 43 are provided on the first inorganic encapsulation film 41, and the second inorganic encapsulation film 43 is provided so as to cover the organic encapsulation film 42 on the first inorganic encapsulation film 41.

In addition, referring to FIGS. 7 and 8, the organic EL display panel 50a includes a plurality of banks R each provided annularly in the non-display area N so as to surround the through hole Ha.

Referring to FIG. 7, each bank R includes: a resin portion 8a formed of the second resin substrate layer 8 in the resin substrate layer 10; and a first inorganic insulating layer 11a, a second inorganic insulating layer 13a, a third inorganic insulating layer 15a, and a fourth inorganic insulating layer 17a that are provided sequentially on the resin portion 8a. Here, the organic EL layer 33 and the second electrode 34 are stacked sequentially, disconnected from those in the display area D, on (the fourth inorganic insulating layer 17a of) each bank R as shown in FIG. 7.

Referring to FIGS. 6, 7, and 8, the resin portion 8a is divided by a plurality of circular slits Sa, Sb, Sc, Sd, and Se each provided annularly in a circular shape in a plan view on the surface of the second resin substrate layer 8 that faces the TFT layer 30, so as to surround the through hole Ha. Note that the organic EL layer 33 and the second electrode 34 are stacked sequentially, disconnected from those in the display area D, on the bottom portion of each slit Sa, Sb, Sc, Sd, and Se as shown in FIGS. 7 and 8. Here, the center of gravity (center) Ca of the through hole Ha in a plan view is located so as to be displaced in a direction further away from the panel edge E (downward in the drawing) than the center of gravity (center) Cb of the slit Se in a plan view is displaced in that direction away from the panel edge E, as shown in FIG. 6, the slit Se being the outermost slit in the plurality of slits Sa, Sb, Sc, Sd, and Se. Note that although the present embodiment discusses the five slits Sa, Sb, Sc, Sd, and Se as an example, the number of the plurality of slits may be, for example, approximately 15.

The first inorganic insulating layer 11a, the second inorganic insulating layer 13a, the third inorganic insulating layer 15a, and the fourth inorganic insulating layer 17a are respectively made of the same material, and provided in the same layer, as the base coat film 11, the gate insulating film 13, the first interlayer insulating film 15, and the second interlayer insulating film 17. Here, in each bank R, the first inorganic insulating layer 11a, the second inorganic insulating layer 13a, the third inorganic insulating layer 15a, and the fourth inorganic insulating layer 17a are provided so as to protrude like an eave from the base of the resin portion 8a toward the through hole Ha and the display area D as shown in FIGS. 7 and 8. In other words, each bank R has a reverse-tapered structure shaped like an eave in which the first inorganic insulating layer 11a, the second inorganic insulating layer 13a, the third inorganic insulating layer 15a, and the fourth inorganic insulating layer 17a are formed wider than the base of the resin portion 8a as shown in FIG. 7. Note that the present embodiment discusses, as an example, a structure in which the first inorganic insulating layer 11a, the second inorganic insulating layer 13a, the third inorganic insulating layer 15a, and the fourth inorganic insulating layer 17a protrude like an eave from the resin portion 8a toward both the through hole Ha and the display area D. Alternatively, the first inorganic insulating layer 11a, the second inorganic insulating layer 13a, the third inorganic insulating layer 15a, and the fourth inorganic insulating layer 17a may protrude like an eave from the resin portion 8a toward either the through hole Ha or the display area D. In these structures, since each bank R has a reverse-tapered structure in the non-display area N, the common organic EL layer 33 and the common second electrode 34 are formed disconnected for the display area D side and for the through hole Ha side by the steps formed by the eave-like reverse-tapered structure. In addition, each bank R may not have a reverse-tapered structure when the common organic EL layer 33 and the common second electrode 34 are formed disconnected for the display area D side and for the through hole Ha side. In addition, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a) in the plurality of banks R and the widths (Jae, Jbe, Jce, Jde, Jad, Jbd, Jcd, and Jdd) of these inorganic insulating layers are relatively large near the panel edge E (see the right-hand side of the drawing) and relatively small opposite the panel edge E (see the left-hand side of the drawing) as shown in FIG. 8. Furthermore, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a) and the widths (Jae, Jbe, Jce, Jde, Jad, Jbd, Jcd, and Jdd) of these inorganic insulating layers are mutually equal near the panel edge E (see the right-hand side of the drawing) and mutually equal opposite the panel edge E (see the left-hand side of the drawing) as shown in FIG. 8. In other words, by using inequality signs, the relationships can be described as in the following.

$$Kae = Kbe = Kce = Kde > Kad = Kbd = Kcd = Kdd$$

$$Jae = Jbe = Jce = Jde > Jad = Jbd = Jcd = Jdd$$

The encapsulation film 45, mentioned earlier, is so formed, in the regions of the non-display area N where the plurality of banks R and the plurality of slits Sa, Sb, Sc, Sd, and Se are located, that the second inorganic encapsulation film 43 is stacked on the first inorganic encapsulation film 41, as shown in FIGS. 7 and 8. Here, the stack of the first inorganic encapsulation film 41 and the second inorganic encapsulation film 43 is provided so as to cover the plurality of banks R and the plurality of slits Sa, Sb, Sc, Sd, and Se as shown in FIGS. 7 and 8.

In addition, referring to FIG. 7, in the non-display area N, the organic EL display panel 50a includes an outer slit St provided annularly on the surface of the second resin substrate layer 8 that faces the TFT layer 30, so as to surround the plurality of slits Sa, Sb, Sc, Sd, and Se. Here, the base coat film 11, the gate insulating film 13, the first interlayer insulating film 15, and the second interlayer insulating film 17 are provided so as to be divided by the outer slit St and to protrude like an eave to the interior of the outer slit St, as shown in FIG. 7. Then, the outer slit St is filled with the organic encapsulation film 42 via the first inorganic encapsulation film 41 as shown in FIG. 7.

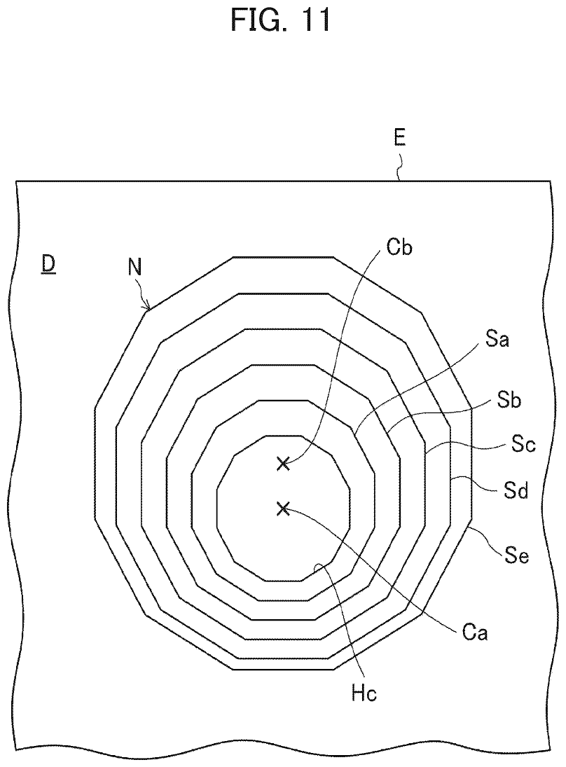

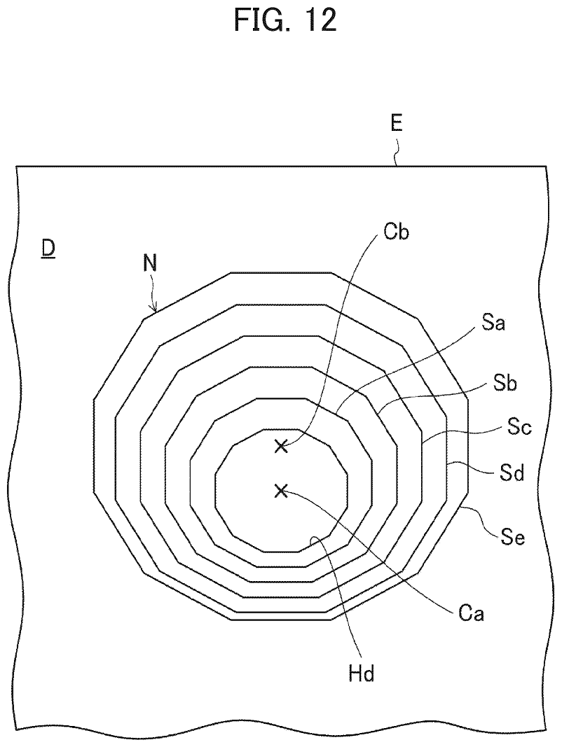

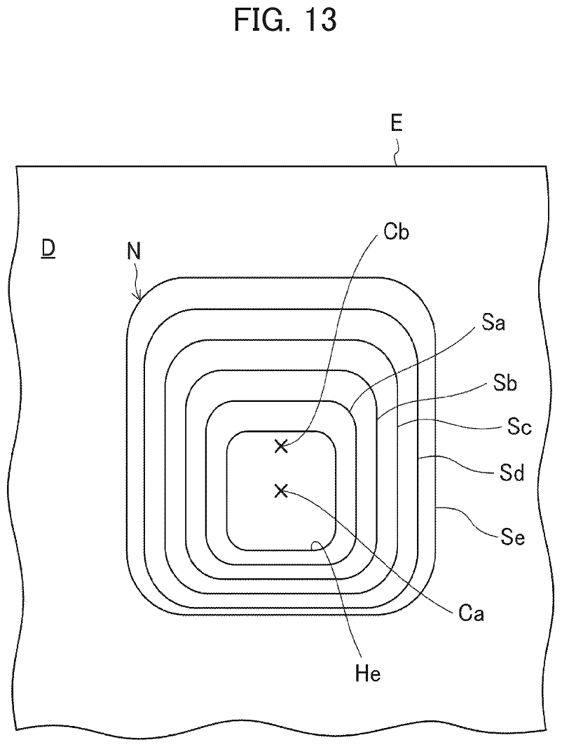

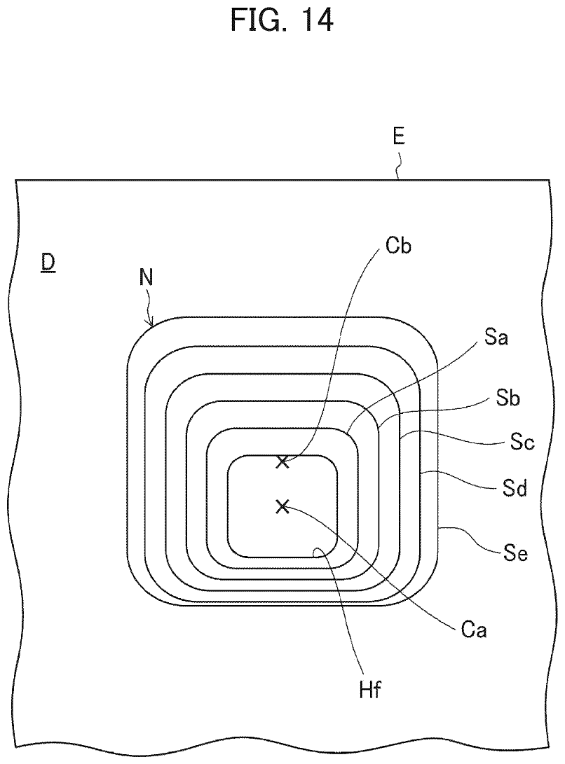

Note that although the present embodiment discusses, as an example, the through hole Ha provided circularly in a plan view, the through hole Ha may be a through hole Hb like the one shown in FIG. 10, a through hole Hc like the one shown in FIG. 11, a through hole Hd like the one shown in FIG. 12, a through hole He like the one shown in FIG. 13, or a through hole Hf like the one shown in FIG. 14.

Specifically, referring to FIG. 10, the through hole Hb is provided in an elliptical shape in a plan view. Here, on the surface of the second resin substrate layer 8 that faces the TFT layer 30, the plurality of slits Sa, Sb, Sc, Sd, and Se are respectively formed annularly in an elliptical shape in a plan view so as to surround the through hole Hb, as shown in FIG. 10. Then, the center of gravity (center) Ca of the through hole Hb in a plan view is located so as to be displaced in a direction further away from the panel edge E (downward in the drawing) than the center of gravity (center) Cb of the slit Se in a plan view is displaced in that direction away from the panel edge E, as shown in FIG. 10, the slit Se being the outermost slit in the plurality of slits Sa, Sb, Sc, Sd, and Se.

In addition, the through hole Hc is provided in a regular dodecagonal shape in a plan view as shown in FIG. 11. Here, on the surface of the second resin substrate layer 8 that faces the TFT layer 30, the plurality of slits Sa, Sb, Sc, Sd, and Se are respectively formed annularly in a regular dodecagonal shape in a plan view so as to surround the through hole Hc, as shown in FIG. 11. Then, the center of gravity (center) Ca of the through hole Hc in a plan view is located so as to be displaced in a direction further away from the panel edge E (downward in the drawing) than the center of gravity (center) Cb of the slit Se in a plan view is displaced in that direction away from the panel edge E, as shown in FIG. 11, the slit Se being the outermost slit in the plurality of slits Sa, Sb, Sc, Sd, and Se.

In addition, the through hole Hd is provided in a dodecagonal shape (pressed vertically in the drawing) in a plan view as shown in FIG. 12. Here, on the surface of the second resin substrate layer 8 that faces the TFT layer 30, the plurality of slits Sa, Sb, Sc, Sd, and Se are respectively formed annularly in a dodecagonal shape in a plan view so as to surround the through hole Hd, as shown in FIG. 12. Then, the center of gravity (center) Ca of the through hole Hd in a plan view is located so as to be displaced in a direction further away from the panel edge E (downward in the drawing) than the center of gravity (center) Cb of the slit Se in a plan view is displaced in that direction away from the panel edge E, as shown in FIG. 12, the slit Se being the outermost slit in the plurality of slits Sa, Sb, Sc, Sd, and Se.

In addition, the through hole He is provided in a generally square shape with corners being shaped like the letter “R” in a plan view as shown in FIG. 13. Here, on the surface of the second resin substrate layer 8 that faces the TFT layer 30, the plurality of slits Sa, Sb, Sc, Sd, and Se are respectively formed annularly in a generally square shape in a plan view so as to surround the through hole He, as shown in FIG. 13. Then, the center of gravity (center) Ca of the through hole He in a plan view is located so as to be displaced in a direction further away from the panel edge E (downward in the drawing) than the center of gravity (center) Cb of the slit Se in a plan view is displaced in that direction away from the panel edge E, as shown in FIG. 13, the slit Se being the outermost slit in the plurality of slits Sa, Sb, Sc, Sd, and Se.

In addition, the through hole Hf is provided in a landscape-oriented, generally rectangular shape in the drawing with corners being shaped like the letter “R” in a plan view as shown in FIG. 14. Here, on the surface of the second resin substrate layer 8 that faces the TFT layer 30, the plurality of slits Sa, Sb, Sc, Sd, and Se are respectively formed annularly in a generally rectangular shape in a plan view so as to surround the through hole Hf, as shown in FIG. 14. Then, the center of gravity (center) Ca of the through hole Hf in a plan view is located so as to be displaced in a direction further away from the panel edge E (downward in the drawing) than the center of gravity (center) Cb of the slit Se in a plan view is displaced in that direction away from the panel edge E, as shown in FIG. 14, the slit Se being the outermost slit in the plurality of slits Sa, Sb, Sc, Sd, and Se.

Note that although the variation examples shown in FIGS. 11 to 14 discuss, as an example, polygonal through holes and slits such as quadrilateral and dodecagonal through holes and slits, the through holes may have another n-gonal shape (n is a natural number greater than or equal to 3). In addition, the through holes and slits may have any shape in a plan view so long as the shape corresponds to the shape of the image sensor 60 in a plan view, and their positional relationship is defined by the center of gravity of the mass center.

In addition, referring to FIG. 7, the organic EL display panel 50a includes, in the non-display area N, an inner damming wall Wc provided annularly between the plurality of slits Sa, Sb, Sc, Sd, and Se and the outer slit St. Here, referring to FIG. 7, the inner damming wall Wc includes a resin layer 32e made of the same material, and provided in the same layer, as the edge cover 32a, is provided so as to come into contact with an inner peripheral portion of the organic encapsulation film 42 via the first inorganic encapsulation film 41, and is structured so as to restrain the ink that will form the organic encapsulation film 42 from spreading.

In addition, referring to FIG. 7, the organic EL display panel 50a includes a first bypass wiring line 16n and a second bypass wiring line 18n that bypass the through hole H around the outer slit St in the non-display area N. Here, the first bypass wiring line 16n is formed of the aforementioned second metal film. In addition, the second bypass wiring line 18n is formed of the aforementioned third metal film. Note that the first bypass wiring line 16n and the second bypass wiring line 18n are electrically connected to the display-use wiring lines (the gate lines 14g, the light-emission control lines 14e, the source lines 18f, and the like) running in a portion that corresponds to the through hole Ha.

In addition, referring to FIG. 1, the organic EL display panel 50a includes, in the frame area F: a first outer damming wall Wa provided in a frame shape outside the trench G so as to surround the display area D; and a second outer damming wall Wb provided in a frame shape around the first outer damming wall Wa.

Referring to FIG. 9, the first outer damming wall Wa includes: a lower resin layer 21b made of the same material, and provided in the same layer, as the second planarization film 21a; and an upper resin layer 32c made of the same material, and provided in the same layer, as the edge cover 32a and provided on the lower resin layer 21b via a connection wiring 31b. Here, the connection wiring 31b is made of the same material, and provided in the same layer, as the first electrodes 31a. Note that the first outer damming wall Wa is provided so as to overlap a peripheral portion of the organic encapsulation film 42 and structured so as to restrain the ink that will form the organic encapsulation film 42 from spreading.

Referring to FIG. 9, the second outer damming wall Wb includes: a lower resin layer 21c made of the same material, and provided in the same layer, as the second planarization film 21a; and an upper resin layer 32d made of the same material, and provided in the same layer, as the edge cover 32a and provided on the lower resin layer 21c via the connection wiring 31b.

In addition, referring to FIG. 1, the organic EL display panel 50a includes, in the frame area F, a first frame line 18h provided in a frame shape inside the trench G and having both ends running into the terminal section T in the open portion of the trench G. Here, the first frame line 18h is structured to be electrically connected to the power supply lines 20a in the display area D via contact holes formed in the first planarization film 19a and to be fed with a high-voltage power supply (ELVDD) in the terminal section T. In addition, the first frame line 18h is formed of the third metal film.

In addition, referring to FIG. 1, the organic EL display panel 50a includes, in the frame area F, a second frame line 18i provided generally like a letter “C” outside the trench G and having both ends running into the terminal section T. Here, referring to FIG. 9, the second frame line 18i is structured to be electrically connected to the second electrode 34 in the display area D via the connection wiring 31b provided in the trench G and to be fed with a low-voltage power supply (ELVSS) in the terminal section T. In addition, the second frame line 18i is formed of the third metal film.

In addition, referring to FIG. 9, the organic EL display panel 50a includes, in the frame area F, a plurality of peripheral photo spacers 32b provided insularly so as to protrude upward at both ends of the trench G. Here, the peripheral photo spacers 32b are made of the same material, and provided in the same layer, as the edge cover 32a.

The image sensor 60 is built around, for example, a CMOS (complementary metal oxide semiconductor) camera or a CCD (charge coupled device) camera. Note that although the present embodiment discusses the image sensor 60 as an example of the electronic component, the electronic component may be an optical sensor such as a fingerprint sensor or a face authentication sensor.

In the above-described organic EL display device 70, an image is displayed by, in each subpixel P, feeding a gate signal to the first TFT 9a via the gate line 14g to turn on the first TFT 9a, writing a prescribed voltage corresponding to a source signal to the gate electrode of the second TFT 9b and to the capacitor 9d via the source line 18f, hence feeding a light-emission control signal to the third TFT 9c via the light-emission control line 14e to turn on the third TFT 9c, and feeding an electric current in accordance with the gate voltage of the second TFT 9b from the power supply line 20a to the organic EL layer 33 so that the organic light-emitting layer 3 in the organic EL layer 33 can emit light. Note that in the organic EL display device 70, even when the first TFT 9a is turned off, the gate voltage of the second TFT 9b is retained by the capacitor 9d, and for this reason, the organic light-emitting layer 3 continuously emits light in each subpixel P until a gate signal is fed in a next frame. In addition, the organic EL display device 70 is structured so that the image sensor 60 installed on the rear of the organic EL display panel 50a can capture an image of an object in front of the organic EL display panel 50a.

A description is given next of a method of manufacturing the organic EL display device 70 in accordance with the present embodiment. Note that the method of manufacturing the organic EL display device 70 in accordance with the present embodiment includes a TFT layer formation step, an organic EL element layer formation step, an encapsulation film formation step, and a through hole formation step.

### TFT Layer Formation Step

First, for example, after applying a non-photosensitive polyimide resin (to a thickness of approximately 6 μm) on a glass substrate, the resultant coating film is subjected to pre-baking and post-baking to form the first resin substrate layer 6.

Subsequently, an inorganic insulating film such as a silicon oxide film (with a thickness of approximately 500 nm) is formed by, for example, plasma CVD (chemical vapor deposition) on the surface of a substrate on which the first resin substrate layer 6 has been formed, to form the intra-substrate inorganic insulating film 7.

Furthermore, for example, after applying a non-photosensitive polyimide resin (to a thickness of approximately 6 μm) on the surface of the substrate on which the intra-substrate inorganic insulating film 7 has been formed, the resultant coating film is subjected to pre-baking and post-baking to form the second resin substrate layer 8, thereby forming the resin substrate layer 10.

Thereafter, a silicon oxide film (with a thickness of approximately 500 nm) and a silicon nitride film (with a thickness of approximately 100 nm) are formed sequentially by, for example, plasma CVD on the surface of the substrate on which the resin substrate layer 10 has been formed, to form the base coat film 11.

Subsequently, after, for example, forming an amorphous silicon film (with a thickness of approximately 50 nm) by plasma CVD on the surface of the substrate on which the base coat film 11 has been formed and crystallizing the amorphous silicon film by, for example, laser annealing to form a semiconductor film of a polysilicon film, the semiconductor film is patterned to form, for example, the semiconductor layer 12a (12b).

Thereafter, an inorganic insulating film such as a silicon oxide film (approximately 100 nm) is formed by, for example, plasma CVD on the surface of the substrate on which, for example, the semiconductor layer 12a has been formed, to form the gate insulating film 13 so as to cover, for example, the semiconductor layer 12a.

Furthermore, after forming the first metal film such as a molybdenum film (with a thickness of approximately 250 nm) by, for example, sputtering on the surface of the substrate on which the gate insulating film 13 has been formed, the first metal film is patterned to form, for example, the gate line 14g and the gate electrode 14a (14b).

Subsequently, for example, the semiconductor layer 12a (12b) is doped with impurity ions by using, for example, the gate electrode 14a (14b) as a mask, to form channel regions, source regions, and drain regions in, for example, the semiconductor layer 12a (12b).

Thereafter, a silicon nitride film (with a thickness of approximately 100 nm) is formed by, for example, plasma CVD on the surface of the substrate in which, for example, the semiconductor layer 12a (12b) has been doped with impurity ions, to form the first interlayer insulating film 15.

Subsequently, after forming the second metal film such as a molybdenum film (with a thickness of approximately 250 nm) by, for example, sputtering on the surface of the substrate on which the first interlayer insulating film 15 has been formed, the second metal film is patterned to form, for example, the overlying conductive layer 16c.

Furthermore, a silicon oxide film (with a thickness of approximately 300 nm) and a silicon nitride film (with a thickness of approximately 200 nm) are formed sequentially by, for example, plasma CVD on the surface of the substrate on which, for example, the overlying conductive layer 16c has been formed, to form the second interlayer insulating film 17.

Thereafter, the gate insulating film 13, the first interlayer insulating film 15, and the second interlayer insulating film 17 are patterned to form contact holes.

Furthermore, the stacked film of the base coat film 11, the gate insulating film 13, the first interlayer insulating film 15, and the second interlayer insulating film 17 is removed from the bending portion B to form band-like slits in the stacked film of the base coat film 11, the gate insulating film 13, the first interlayer insulating film 15, and the second interlayer insulating film 17.

Subsequently, after forming the third metal film by forming, for example, a titanium film (with a thickness of approximately 50 nm), an aluminum film (with a thickness of approximately 600 nm), and a titanium film (with a thickness of approximately 50 nm) sequentially by, for example, sputtering on the surface of the substrate on which the band-like slits have been formed, the third metal film is patterned to form, for example, the source line 18f.

Furthermore, after applying a photosensitive polyimide resin (to a thickness of approximately 2.5 μm) by, for example, spin-coating or slit-coating on the surface of the substrate on which, for example, the source line 18f has been formed, the resultant coating film is subjected to pre-baking, exposure to light, development, and post-baking, to form, for example, the first planarization film 19a.

Thereafter, after forming the fourth metal film by forming, for example, a titanium film (with a thickness of approximately 50 nm), an aluminum film (with a thickness of approximately 600 nm), and a titanium film (with a thickness of approximately 50 nm) sequentially by, for example, sputtering on the surface of the substrate on which, for example, the first planarization film 19a has been formed, the fourth metal film is patterned to form, for example, the power supply lines 20a.

Finally, after applying a polyimide-based photosensitive resin film (with a thickness of approximately 2.5 μm) by, for example, spin-coating or slit-coating on the surface of the substrate on which, for example, the power supply lines 20a have been formed, the resultant coating film is subjected to pre-baking, exposure to light, development, and post-baking, to form, for example, the second planarization film 21a.

The TFT layer 30 can be formed as described above.

### Organic EL Element Layer Formation Step

The first electrodes 31a, the edge cover 32a, the organic EL layer 33 (the hole injection layer 1, the hole transport layer 2, the organic light-emitting layer 3, the electron transport layer 4, and the electron injection layer 5) and the second electrode 34 are formed by a well-known method on the second planarization film 21a in the TFT layer 30 formed in the TFT layer formation step described above, to form the organic EL element layer 40. Here, the plurality of banks R are formed by, after forming the first electrodes 31a, partially removing the stacked film of the base coat film 11, the gate insulating film 13, the first interlayer insulating film 15, the second interlayer insulating film 17, and a third wiring layer in the non-display area N and then ashing the second resin substrate layer 8 exposed out of the stacked film of the base coat film 11, the gate insulating film 13, the first interlayer insulating film 15, the second interlayer insulating film 17, and the third wiring layer, to form the plurality of slits Sa, Sb, Sc, Sd, and Se (and the outer slit St). Note that although the present embodiment discusses, as an example, a manufacturing method where the banks R are formed in an organic EL element layer formation step, the banks R may be formed in the TFT layer formation step.

### Sealing Film Formation Step

First, on the surface of the substrate on which the organic EL element layer 40 formed in the organic EL element layer formation step has been formed, an inorganic insulating film such as a silicon nitride film, a silicon oxide film, or a silicon oxynitride film is formed by plasma CVD using a mask, to form the first inorganic encapsulation film 41.

Subsequently, a film of an organic resin material such as an acrylic resin is formed, by, for example, inkjet printing technology on the surface of the substrate on which the first inorganic encapsulation film 41 has been formed, to form the organic encapsulation film 42.

Thereafter, on the surface of the substrate on which the organic encapsulation film 42 have been formed, the second inorganic encapsulation film 43 is formed by forming an inorganic insulating film such as a silicon nitride film, a silicon oxide film, or a silicon oxynitride film by plasma CVD using a mask, to form the encapsulation film 45.

Furthermore, after attaching a front-side protection sheet (not shown) to the surface of the substrate on which the encapsulation film 45 has been formed, the glass substrate is detached from the bottom surface of the resin substrate layer 10 by projecting laser light onto the glass-substrate side of the resin substrate layer 10, and furthermore, a backside protection sheet (not shown) is attached to the bottom surface of the resin substrate layer 10 from which the glass substrate has been detached.

The organic EL display panel 50a can be formed as described above.

### Through Hole Formation Step

The through hole Ha is formed by, for example, projecting laser light, while annularly moving the laser light, onto the non-display area N of the organic EL display panel 50a formed in the encapsulation film formation step. Thereafter, the image sensor 60 is installed so that the image sensor 60 such as a camera is positioned on the backside of the through hole Ha when the organic EL display panel 50a in which the through hole Ha has been formed is, for example, fixed inside a housing.

The organic EL display device 70 in accordance with the present embodiment can be manufactured as described above.

As described above, in the organic EL display device 70 in accordance with the present embodiment, the non-display area N is provided insularly inside the display area D along the panel edge E of the organic EL display panel 50a, the through hole Ha running through the organic EL display panel 50a in its thickness direction is provided in the non-display area N, and the plurality of annular banks R are provided so as to surround the through hole Ha. Here, the resin portion 8a of each bank R is divided by the plurality of slits Sa, Sb, Sc, Sd, and Se each formed annularly on the surface of the second resin substrate layer 8 that faces the TFT layer 30, so as to surround the through hole Ha. Then, the center of gravity (center) Ca of the through hole Ha in a plan view is located so as to be displaced in a direction further away from the panel edge E than the center of gravity (center) Cb of the slit Se in a plan view is displaced in that direction away from the panel edge E, the slit Se being the outermost slit in the plurality of slits Sa, Sb, Sc, Sd, and Se. This particular structure can further separate the through hole Ha from the panel edge E than in a case where the through hole (Ha) is concentric to the plurality of slits (Sa, Sb, Sc, Sd, and Se), thereby slowing down the penetration of moisture and like water content into the organic EL layer 33 on the panel edge E side of the through hole Ha, and can therefore restrain degradation of the organic EL layer 33 on the panel edge E side of the through hole Ha. Hence, in the organic EL display device 70 including the plurality of banks R that use the resin substrate layer 10 around the through hole Ha, the structure can restrain degradation of the organic EL layer 33 on the panel edge E side of the through hole Ha, thereby improving the reliability of the organic EL display device 70.

In addition, in the organic EL display device 70 in accordance with the present embodiment, since the intervals between the inorganic insulating layers in the plurality of banks R and the widths of these inorganic insulating layers are constant, the reliability of the organic EL display device 70 can be further improved by increasing these intervals.

### Second Embodiment

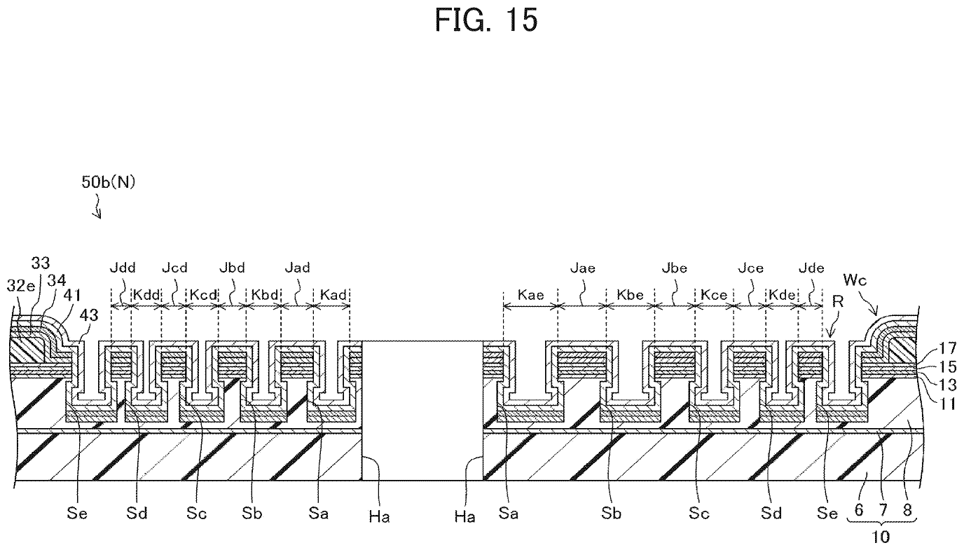

FIG. 15 illustrates a second embodiment of the display device in accordance with the disclosure. Here, FIG. 15 is a cross-sectional view of a non-display area N of an organic EL display panel 50b that is a part of an organic EL display device in accordance with the present embodiment and corresponds to FIG. 8. Note that members of this and subsequent embodiments that are the same as those shown in FIGS. 1 to 14 are denoted by the same reference signs or numerals, and detailed description thereof is omitted.

The first embodiment has discussed, as an example, the organic EL display device 70 including the organic EL display panel 50a in which the intervals between inorganic insulating layers in a plurality of banks and the widths of these inorganic insulating layers are mutually equal near the panel edge and mutually equal opposite the panel edge. As an alternative, this and subsequent embodiments discuss, as an example, an organic EL display device including an organic EL display panel in which the intervals between inorganic insulating layers in a plurality of banks and the widths of these inorganic insulating layers are mutually different near the panel edge and mutually different opposite the panel edge. Note that the present embodiment discusses, as an example, an organic EL display device including the organic EL display panel 50b in which either the intervals between inorganic insulating layers in a plurality of banks or the widths of these inorganic insulating layers or both are provided so as to become smaller when moving away from the through hole.

Similarly to the foregoing organic EL display device 70 in accordance with the first embodiment, the organic EL display device in accordance with the present embodiment includes: the organic EL display panel 50b having the through hole Ha in the non-display area N; and an image sensor 60 installed on the backside of the through hole Ha in the organic EL display panel 50b.

Similarly to the foregoing organic EL display panel 50a in accordance with the first embodiment, the organic EL display panel 50b has a display area D and a frame area F provided around the display area D.

In addition, similarly to the foregoing organic EL display panel 50a in accordance with the first embodiment, the organic EL display panel 50b includes: a resin substrate layer 10; a TFT layer 30 provided on the resin substrate layer 10; an organic EL element layer 40 provided on the TFT layer 30; and an encapsulation film 45 provided on the organic EL element layer 40.

In addition, similarly to the foregoing organic EL display panel 50a in accordance with the first embodiment, the organic EL display panel 50b includes a plurality of banks R each provided annularly in the non-display area N so as to surround the through hole Ha as shown in FIG. 15. Here, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a; see FIG. 7) in the plurality of banks R and the widths (Jae, Jbe, Jce, Jde, Jad, Jbd, Jcd, and Jdd) of these inorganic insulating layers are relatively large near the panel edge E (see the right-hand side of the drawing) and relatively small opposite the panel edge E (see the left-hand side of the drawing) as shown in FIG. 15. Furthermore, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a) and the widths (Jae, Jbe, Jce, Jde, Jad, Jbd, Jcd, and Jdd) of these inorganic insulating layers become smaller when moving away from the through hole Ha as shown in FIG. 15. In other words, by using inequality signs, the relationships can be described as in the following.

$$Kae > Kbe > Kce > Kde , Kad > Kbd > Kcd > Kdd$$

$$Jae > Jbe > Jce > Jde , Jad > Jbd > Jcd > Jdd$$

Note that the present embodiment has discussed, as an example, a structure in which both the intervals between inorganic insulating layers and the widths of these inorganic insulating layers become smaller when moving away from the through hole Ha. Alternatively, the structure may be such that either the intervals between the inorganic insulating layers or the widths of these inorganic insulating layers become smaller when moving away from the through hole Ha. In other words, by using inequality signs, the relationships may be described as in the following.

$$Kae = Kbe = Kce = Kde > Kad = Kbd = Kcd = Kdd$$

$$Jae > Jbe > Jce > Jde , Jad > Jbd > Jcd > Jdd$$

$$or$$

$$Kae > Kbe > Kce > Kde , Kad > Kbd > Kcd > Kdd$$

$$Jae = Jbe = Jce = Jde > Jad = Jbd = Jcd = Jdd$$

In addition, the present embodiment has discussed, as an example, the through hole Ha provided circularly in a plan view. Alternatively, similarly to the foregoing organic EL display panel 50a in accordance with the first embodiment, the through hole Ha may have another shape in a plan view, for example, like the through holes Hb, Hc, Hd, and Hf.

In addition, similarly to the foregoing organic EL display panel 50a in accordance with the first embodiment, the organic EL display panel 50b includes, in the non-display area N, an outer slit St provided annularly on the surface of the second resin substrate layer 8 that faces the TFT layer 30, so as to surround the plurality of slits Sa, Sb, Sc, Sd, and Se.

In addition, similarly to the foregoing organic EL display panel 50a in accordance with the first embodiment, the organic EL display panel 50b includes, in the non-display area N, an inner damming wall Wc provided annularly between the plurality of slits Sa, Sb, Sc, Sd, and Se and the outer slit St.

In addition, similarly to the foregoing organic EL display panel 50a in accordance with the first embodiment, the organic EL display panel 50b includes, in the non-display area N, a first bypass wiring line 16n and a second bypass wiring line 18n that bypass the through hole H around the outer slit St.

In addition, similarly to the foregoing organic EL display panel 50a in accordance with the first embodiment, the organic EL display panel 50b includes, in the frame area F: a first outer damming wall Wa provided outside a trench G so as to surround the display area D; and a second outer damming wall Wb provided around the first outer damming wall Wa.

In addition, similarly to the foregoing organic EL display panel 50a in accordance with the first embodiment, the organic EL display panel 50b includes, in the frame area F: a first frame line 18h provided inside the trench G; and a second frame line 18i provided outside the trench G.

In addition, similarly to the foregoing organic EL display panel 50a in accordance with the first embodiment, the organic EL display panel 50b includes, in the frame area F, a plurality of peripheral photo spacers 32b provided so as to protrude upward at both ends of the trench G.

Similarly to the foregoing organic EL display device 70 in accordance with the first embodiment, the organic EL display device including the above-described organic EL display panel 50b is flexible, displays images by causing the organic light-emitting layer 3 in the organic EL layer 33 in each subpixel P to emit light in a suitable manner via the first TFT 9a, the second TFT 9b, and the third TFT 9c, and is structured to capture an image of an object in front of the organic EL display panel 50b by using the image sensor 60 installed on the rear of the organic EL display panel 50b.

The organic EL display device including the organic EL display panel 50b in accordance with the present embodiment can be manufactured by changing the pattern shape in partially removing the stacked film of the base coat film 11, the gate insulating film 13, the first interlayer insulating film 15, the second interlayer insulating film 17, and the third wiring layer from the non-display area N in the aforementioned organic EL element layer formation step in the method of manufacturing the organic EL display device 70 in accordance with the first embodiment.

As described above, in the organic EL display device including the organic EL display panel 50b in accordance with the present embodiment, the non-display area N is provided insularly inside the display area D along the panel edge E of the organic EL display panel 50b, the through hole Ha running through the organic EL display panel 50b in its thickness direction is provided in the non-display area N, and the plurality of annular banks R are provided so as to surround the through hole Ha. Here, the resin portion 8a of each bank R is divided by the plurality of slits Sa, Sb, Sc, Sd, and Se each formed annularly on the surface of the second resin substrate layer 8 that faces the TFT layer 30, so as to surround the through hole Ha. Then, the center of gravity (center) Ca of the through hole Ha in a plan view is located so as to be displaced in a direction further away from the panel edge E than the center of gravity (center) Cb of the slit Se in a plan view is displaced in that direction away from the panel edge E, the slit Se being the outermost slit in the plurality of slits Sa, Sb, Sc, Sd, and Se. This particular structure can further separate the through hole Ha from the panel edge E than in a case where the through hole (Ha) is concentric to the plurality of slits (Sa, Sb, Sc, Sd, and Se), thereby slowing down the penetration of moisture and like water content into the organic EL layer 33 on the panel edge E side of the through hole Ha, and can therefore restrain degradation of the organic EL layer 33 on the panel edge E side of the through hole Ha. Hence, in the organic EL display device including the organic EL display panel 50b including the plurality of banks R that use the resin substrate layer 10 around the through hole Ha, the structure can restrain degradation of the organic EL layer 33 on the panel edge E side of the through hole Ha, thereby improving the reliability of the organic EL display device.

### Third Embodiment

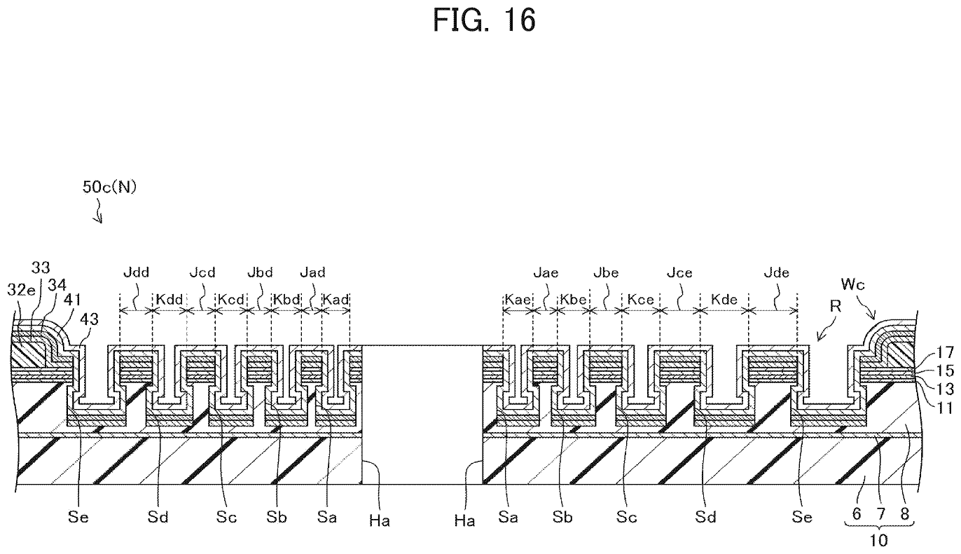

FIG. 16 illustrates a third embodiment of the display device in accordance with the disclosure. Here, FIG. 16 is a cross-sectional view of the non-display area N of an organic EL display panel 50c that is a part of an organic EL display device in accordance with the present embodiment and corresponds to FIG. 8. Note that the present embodiment discusses, as an example, an organic EL display device including the organic EL display panel 50c in which either the intervals between inorganic insulating layers in a plurality of banks or the widths of these inorganic insulating layers or both are provided so as to become larger when moving away from the through hole.

Similarly to the foregoing organic EL display device 70 in accordance with the first embodiment, the organic EL display device in accordance with the present embodiment includes: the organic EL display panel 50c having the through hole Ha in the non-display area N; and an image sensor 60 installed on the backside of the through hole Ha in the organic EL display panel 50c.

Similarly to the foregoing organic EL display panel 50a in accordance with the first embodiment, the organic EL display panel 50c has a display area D and a frame area F provided around the display area D.

In addition, similarly to the foregoing organic EL display panel 50a in accordance with the first embodiment, the organic EL display panel 50c includes: a resin substrate layer 10; a TFT layer 30 provided on the resin substrate layer 10; an organic EL element layer 40 provided on the TFT layer 30; and an encapsulation film 45 provided on the organic EL element layer 40.

In addition, similarly to the foregoing organic EL display panel 50a in accordance with the first embodiment, the organic EL display panel 50c includes a plurality of banks R each provided annularly so as to surround the through hole Ha in the non-display area N as shown in FIG. 16. Here, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a; see FIG. 7) in the plurality of banks R and the widths (Jae, Jbe, Jce, Jde, Jad, Jbd, Jcd, and Jdd) of these inorganic insulating layers are relatively large near the panel edge E (see the right-hand side of the drawing) and relatively small opposite the panel edge E (see the left-hand side of the drawing) as shown in FIG. 16. Furthermore, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a) and the widths (Jae, Jbe, Jce, Jde, Jad, Jbd, Jcd, and Jdd) of these inorganic insulating layers become larger when moving away from the through hole Ha as shown in FIG. 16. In other words, by using inequality signs, the relationships can be described as in the following.

$$Kae < Kbe < Kce < Kde , Kad < Kbd < Kcd < Kdd$$

$$Jae < Jbe < Jce < Jde , Jad < Jbd < Jcd < Jdd$$

Note that the present embodiment has discussed, as an example, a structure in which both the intervals between the inorganic insulating layers and the widths of these inorganic insulating layers become larger when moving away from the through hole Ha. Alternatively, the structure may be such that either the intervals between the inorganic insulating layers or the widths of these inorganic insulating layers become larger when moving away from the through hole Ha. In other words, by using inequality signs, the relationships may be described as in the following.

$$Kae = Kbe = Kce = Kde > Kad = Kbd = Kcd = Kdd$$

$$Jae < Jbe < Jce < Jde , Jad < Jbd < Jcd < Jdd$$

$$or$$

$$Kae < Kbe < Kce < Kde , Kad < Kbd < Kcd < Kdd$$

$$Jae = Jbe = Jce = Jde > Jad = Jbd = Jcd = Jdd$$

In addition, the present embodiment has discussed, as an example, the through hole Ha provided circularly in a plan view. Alternatively, similarly to the foregoing organic EL display panel 50a in accordance with the first embodiment, the through hole Ha may have another shape in a plan view, for example, like the through holes Hb, Hc, Hd, and Hf.

In addition, similarly to the foregoing organic EL display panel 50a in accordance with the first embodiment, the organic EL display panel 50c includes, in the non-display area N, an outer slit St provided annularly on the surface of the second resin substrate layer 8 that faces the TFT layer 30, so as to surround the plurality of slits Sa, Sb, Sc, Sd, and Se.

In addition, similarly to the foregoing organic EL display panel 50a in accordance with the first embodiment, the organic EL display panel 50c includes, in the non-display area N, an inner damming wall Wc provided annularly between the plurality of slits Sa, Sb, Sc, Sd, and Se and the outer slit St.

In addition, similarly to the foregoing organic EL display panel 50a in accordance with the first embodiment, the organic EL display panel 50c includes, in the non-display area N, a first bypass wiring line 16n and a second bypass wiring line 18n that bypass the through hole H around the outer slit St.

In addition, similarly to the foregoing organic EL display panel 50a in accordance with the first embodiment, the organic EL display panel 50c includes, in the frame area F: a first outer damming wall Wa provided outside a trench G so as to surround the display area D; and a second outer damming wall Wb provided around the first outer damming wall Wa.

In addition, similarly to the foregoing organic EL display panel 50a in accordance with the first embodiment, the organic EL display panel 50c includes, in the frame area F: a first frame line 18h provided inside the trench G; and a second frame line 18i provided outside the trench G.

In addition, similarly to the foregoing organic EL display panel 50a in accordance with the first embodiment, the organic EL display panel 50c includes, in the frame area F, a plurality of peripheral photo spacers 32b provided so as to protrude upward at both ends of the trench G.

Similarly to the foregoing organic EL display device 70 in accordance with the first embodiment, the organic EL display device including the above-described organic EL display panel 50c is flexible, displays images by causing the organic light-emitting layer 3 in the organic EL layer 33 in each subpixel P to emit light in a suitable manner via the first TFT 9a, the second TFT 9b, and the third TFT 9c, and is structured to capture an image of an object in front of the organic EL display panel 50c by using the image sensor 60 installed on the rear of the organic EL display panel 50c.

The organic EL display device including the organic EL display panel 50c in accordance with the present embodiment can be manufactured by changing the pattern shape in partially removing the stacked film of the base coat film 11, the gate insulating film 13, the first interlayer insulating film 15, the second interlayer insulating film 17, and the third wiring layer from the non-display area N in the aforementioned organic EL element layer formation step in the method of manufacturing the organic EL display device 70 in accordance with the first embodiment.

As described above, in the organic EL display device including the organic EL display panel 50c in accordance with the present embodiment, the non-display area N is provided insularly inside the display area D along the panel edge E of the organic EL display panel 50c, the through hole Ha running through the organic EL display panel 50c in its thickness direction is provided in the non-display area N, and the plurality of annular banks R are provided so as to surround the through hole Ha. Here, the resin portion 8a of each bank R is divided by the plurality of slits Sa, Sb, Sc, Sd, and Se each formed annularly on the surface of the second resin substrate layer 8 that faces the TFT layer 30, so as to surround the through hole Ha. Then, the center of gravity (center) Ca of the through hole Ha in a plan view is located so as to be displaced in a direction further away from the panel edge E than the center of gravity (center) Cb of the slit Se in a plan view is displaced in that direction away from the panel edge E, the slit Se being the outermost slit in the plurality of slits Sa, Sb, Sc, Sd, and Se. This particular structure can further separate the through hole Ha from the panel edge E than in a case where the through hole (Ha) is concentric to the plurality of slits (Sa, Sb, Sc, Sd, and Se), thereby slowing down the penetration of moisture and like water content into the organic EL layer 33 on the panel edge E side of the through hole Ha, and can therefore restrain degradation of the organic EL layer 33 on the panel edge E side of the through hole Ha. Hence, in the organic EL display device including the organic EL display panel 50c including the plurality of banks R that use the resin substrate layer 10 around the through hole Ha, the structure can restrain degradation of the organic EL layer 33 on the panel edge E side of the through hole Ha, thereby improving the reliability of the organic EL display device.

### Fourth Embodiment

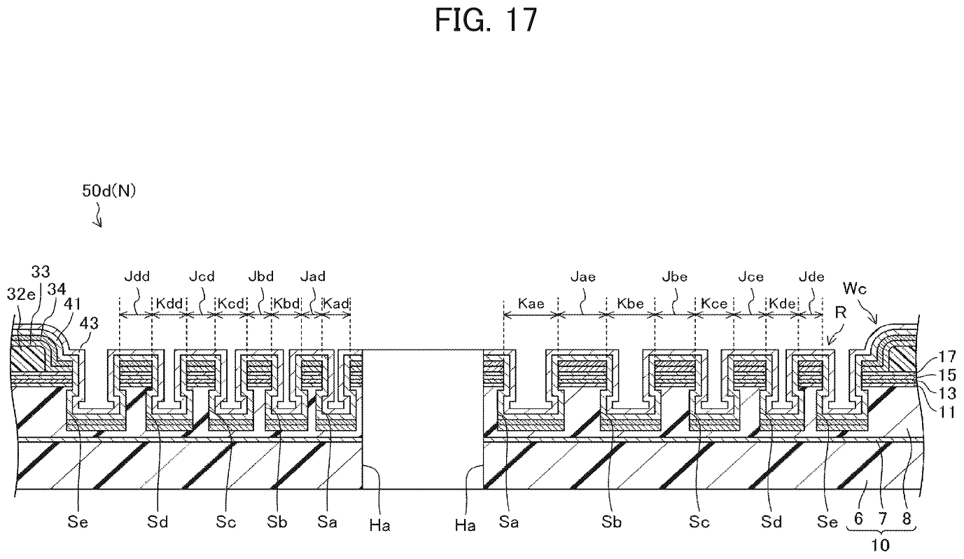

FIG. 17 illustrates a fourth embodiment of the display device in accordance with the disclosure. Here, FIG. 17 is a cross-sectional view of the non-display area N of an organic EL display panel 50d that is a part of an organic EL display device in accordance with the present embodiment and corresponds to FIG. 8. Note that the present embodiment discusses, as an example, an organic EL display device including the organic EL display panel 50d in which either the intervals between inorganic insulating layers in a plurality of banks or the widths of these inorganic insulating layers or both are provided so as to become smaller when moving away from the through hole near the panel edge and to become larger when moving away from the through hole opposite the panel edge.

Similarly to the foregoing organic EL display device 70 in accordance with the first embodiment, the organic EL display device in accordance with the present embodiment includes: the organic EL display panel 50d having the through hole Ha in the non-display area N; and an image sensor 60 installed on the backside of the through hole Ha in the organic EL display panel 50d.

Similarly to the foregoing organic EL display panel 50a in accordance with the first embodiment, the organic EL display panel 50d has a display area D and a frame area F provided around the display area D.

In addition, similarly to the foregoing organic EL display panel 50a in accordance with the first embodiment, the organic EL display panel 50d includes: a resin substrate layer 10; a TFT layer 30 provided on the resin substrate layer 10; an organic EL element layer 40 provided on the TFT layer 30; and an encapsulation film 45 provided on the organic EL element layer 40.

In addition, similarly to the foregoing organic EL display panel 50a in accordance with the first embodiment, the organic EL display panel 50d includes a plurality of banks R each provided annularly so as to surround the through hole Ha in the non-display area N as shown in FIG. 17. Here, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a; see FIG. 7) in the plurality of banks R and the widths (Jae, Jbe, Jce, Jde, Jad, Jbd, Jcd, and Jdd) of these inorganic insulating layers are relatively large near the panel edge E (see the right-hand side of the drawing) and relatively small opposite the panel edge E (see the left-hand side of the drawing) as shown in FIG. 17. Furthermore, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a) and the widths (Jae, Jbe, Jce, Jde, Jad, Jbd, Jcd, and Jdd) of these inorganic insulating layers become smaller when moving away from the through hole Ha near the panel edge E (see the right-hand side of the drawing) and become larger when moving away from the through hole Ha opposite the panel edge E (see the left-hand side of the drawing) as shown in FIG. 17. In other words, by using inequality signs, the relationships can be described as in the following.

$$Kae > Kbe > Kce > Kde , Kad < Kbd < Kcd < Kdd$$

$$Jae > Jbe > Jce > Jde , Jad < Jbd < Jcd < Jdd$$

Note that the present embodiment has discussed, as an example, a structure in which both the intervals between the inorganic insulating layers and the widths of these inorganic insulating layers become smaller when moving away from the through hole Ha near the panel edge E and become larger when moving away from the through hole Ha opposite the panel edge E. Alternatively, the structure may be such that either the intervals between the inorganic insulating layers or the widths of these inorganic insulating layers become smaller when moving away from the through hole Ha near the panel edge E and become larger when moving away from the through hole Ha opposite the panel edge E. In other words, by using inequality signs, the relationships may be described as in the following.

$$Kae = Kbe = Kce = Kde > Kad = Kbd = Kcd = Kdd$$

$$Jae > Jbe > Jce > Jde , Jad < Jbd < Jcd < Jdd$$

$$or$$

$$Kae > Kbe > Kce > Kde , Kad < Kbd < Kcd < Kdd$$

$$Jae = Jbe = Jce = Jde > Jad = Jbd = Jcd = Jdd$$

In addition, the present embodiment has discussed, as an example, the through hole Ha provided circularly in a plan view. Alternatively, similarly to the foregoing organic EL display panel 50a in accordance with the first embodiment, the through hole Ha may have another shape in a plan view, for example, like the through holes Hb, Hc, Hd, and Hf.

In addition, similarly to the foregoing organic EL display panel 50a in accordance with the first embodiment, the organic EL display panel 50d includes, in the non-display area N, an outer slit St provided annularly on the surface of the second resin substrate layer 8 that faces the TFT layer 30, so as to surround the plurality of slits Sa, Sb, Sc, Sd, and Se.

In addition, similarly to the foregoing organic EL display panel 50a in accordance with the first embodiment, the organic EL display panel 50d includes, in the non-display area N, an inner damming wall Wc provided annularly between the plurality of slits Sa, Sb, Sc, Sd, and Se and the outer slit St.

In addition, similarly to the foregoing organic EL display panel 50a in accordance with the first embodiment, the organic EL display panel 50d includes, in the non-display area N, a first bypass wiring line 16n and a second bypass wiring line 18n that bypass the through hole H around the outer slit St.

In addition, similarly to the foregoing organic EL display panel 50a in accordance with the first embodiment, the organic EL display panel 50d includes, in the frame area F: a first outer damming wall Wa provided outside a trench G so as to surround the display area D; and a second outer damming wall Wb provided around the first outer damming wall Wa.

In addition, similarly to the foregoing organic EL display panel 50a in accordance with the first embodiment, the organic EL display panel 50d includes, in the frame area F: a first frame line 18h provided inside the trench G; and a second frame line 18i provided outside the trench G.

In addition, similarly to the foregoing organic EL display panel 50a in accordance with the first embodiment, the organic EL display panel 50d includes, in the frame area F, a plurality of peripheral photo spacers 32b provided so as to protrude upward at both ends of the trench G.

Similarly to the foregoing organic EL display device 70 in accordance with the first embodiment, the organic EL display device including the above-described organic EL display panel 50d is flexible, displays images by causing the organic light-emitting layer 3 in the organic EL layer 33 in each subpixel P to emit light in a suitable manner via the first TFT 9a, the second TFT 9b, and the third TFT 9c, and is structured to capture an image of an object in front of the organic EL display panel 50d by using the image sensor 60 installed on the rear of the organic EL display panel 50d.

The organic EL display device including the organic EL display panel 50d in accordance with the present embodiment can be manufactured by changing the pattern shape in partially removing the stacked film of the base coat film 11, the gate insulating film 13, the first interlayer insulating film 15, the second interlayer insulating film 17, and the third wiring layer from the non-display area N in the aforementioned organic EL element layer formation step in the method of manufacturing the organic EL display device 70 in accordance with the first embodiment.

As described above, in the organic EL display device including the organic EL display panel 50d in accordance with the present embodiment, the non-display area N is provided insularly inside the display area D along the panel edge E of the organic EL display panel 50d, the through hole Ha running through the organic EL display panel 50d in its thickness direction is provided in the non-display area N, and the plurality of annular banks R are provided so as to surround the through hole Ha. Here, the resin portion 8a of each bank R is divided by the plurality of slits Sa, Sb, Sc, Sd, and Se each formed annularly on the surface of the second resin substrate layer 8 that faces the TFT layer 30, so as to surround the through hole Ha. Then, the center of gravity (center) Ca of the through hole Ha in a plan view is located so as to be displaced in a direction further away from the panel edge E than the center of gravity (center) Cb of the slit Se in a plan view is displaced in that direction away from the panel edge E, the slit Se being the outermost slit in the plurality of slits Sa, Sb, Sc, Sd, and Se. This particular structure can further separate the through hole Ha from the panel edge E than in a case where the through hole (Ha) is concentric to the plurality of slits (Sa, Sb, Sc, Sd and Se), thereby slowing down the penetration of moisture and like water content into the organic EL layer 33 on the panel edge E side of the through hole Ha, and can therefore restrain degradation of the organic EL layer 33 on the panel edge E side of the through hole Ha. Hence, in the organic EL display device including the organic EL display panel 50d including the plurality of banks R that use the resin substrate layer 10 around the through hole Ha, the structure can restrain degradation of the organic EL layer 33 on the panel edge E side of the through hole Ha, thereby improving the reliability of the organic EL display device.

### Fifth Embodiment

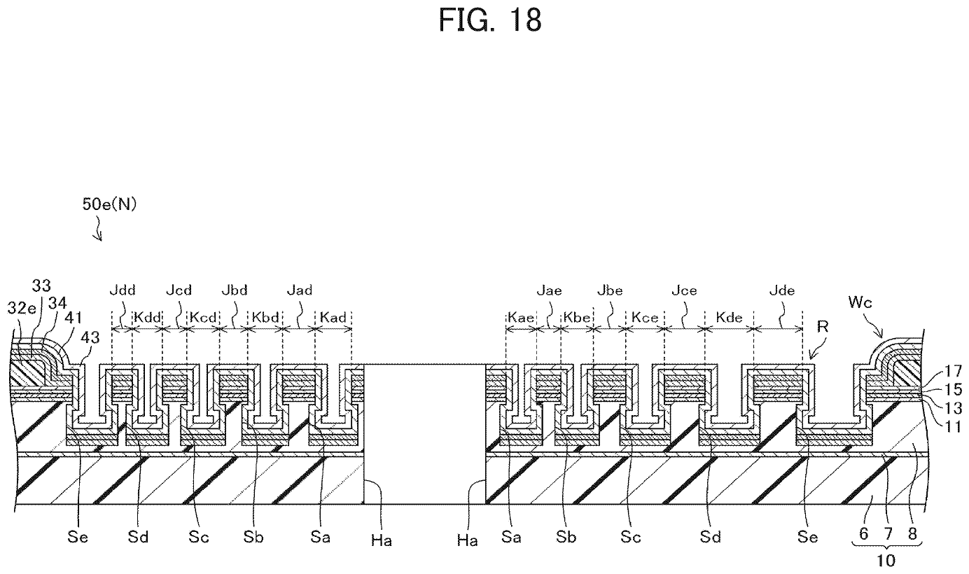

FIG. 18 illustrates a fifth embodiment of the display device in accordance with the disclosure. Here, FIG. 18 is a cross-sectional view of the non-display area N of an organic EL display panel 50e that is a part of an organic EL display device in accordance with the present embodiment and corresponds to FIG. 8. Note that the present embodiment discusses, as an example, an organic EL display device including the organic EL display panel 50e in which either the intervals between inorganic insulating layers in a plurality of banks or the widths of these inorganic insulating layers or both are provided so as to become larger when moving away from the through hole near the panel edge and to become smaller when moving away from the through hole opposite the panel edge.

Similarly to the foregoing organic EL display device 70 in accordance with the first embodiment, the organic EL display device in accordance with the present embodiment includes: the organic EL display panel 50e having the through hole Ha in the non-display area N; and an image sensor 60 installed on the backside of the through hole Ha in the organic EL display panel 50e.

Similarly to the foregoing organic EL display panel 50a in accordance with the first embodiment, the organic EL display panel 50e has a display area D and a frame area F provided around the display area D.

In addition, similarly to the foregoing organic EL display panel 50a in accordance with the first embodiment, the organic EL display panel 50e includes: a resin substrate layer 10; a TFT layer 30 provided on the resin substrate layer 10; an organic EL element layer 40 provided on the TFT layer 30; and an encapsulation film 45 provided on the organic EL element layer 40.

In addition, similarly to the foregoing organic EL display panel 50a in accordance with the first embodiment, the organic EL display panel 50e includes a plurality of banks R each annularly provided so as to surround the through hole Ha in the non-display area N as shown in FIG. 18. Here, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a; see FIG. 7) in the plurality of banks R and the widths (Jae, Jbe, Jce, Jde, Jad, Jbd, Jcd, and Jdd) of these inorganic insulating layers are relatively large near the panel edge E (see the right-hand side of the drawing) and relatively small opposite the panel edge E (see the left-hand side of the drawing) as shown in FIG. 18. Furthermore, the intervals (Kae, Kbe, Kce, Kde, Kad, Kbd, Kcd, and Kdd) between the inorganic insulating layers (the first inorganic insulating layer 11a, the second inorganic insulating layer 13a, the third inorganic insulating layer 15a, and the fourth inorganic insulating layer 17a) and the widths (Jae, Jbe, Jce, Jde, Jad, Jbd, Jcd, and Jdd) of these inorganic insulating layers become larger when moving away from the through hole Ha near the panel edge E (see the right-hand side of the drawing) and become smaller when moving away from the through hole Ha opposite the panel edge E (see the left-hand side of the drawing) as shown in FIG. 18. In other words, by using inequality signs, the relationships can be described as in the following.

$$Kae < Kbe < Kce < Kde , Kad > Kbd > Kcd > Kdd$$

$$Jae < Jbe < Jce < Jde , Jad > Jbd > Jcd > Jdd$$

Note that the present embodiment has discussed, as an example, a structure in which both the intervals between the inorganic insulating layers and the widths of these inorganic insulating layers become larger when moving away from the through hole Ha near the panel edge E and become smaller when moving away from the through hole Ha opposite the panel edge E. Alternatively, the structure may be such that either the intervals between the inorganic insulating layers or the widths of these inorganic insulating layers become larger when moving away from the through hole Ha near the panel edge E and become smaller when moving away from the through hole Ha opposite the panel edge E. In other words, by using inequality signs, the relationships may be described as in the following.

$$Kae = Kbe = Kce = Kde > Kad = Kbd = Kcd = Kdd$$

$$Jae < Jbe < Jce < Jde , Jad > Jbd > Jcd > Jdd$$

$$or$$

$$Kae < Kbe < Kce < Kde , Kad > Kbd > Kcd > Kdd$$

$$Jae = Jbe = Jce = Jde > Jad = Jbd = Jcd = Jdd$$

In addition, the present embodiment has discussed, as an example, the through hole Ha provided circularly in a plan view. Alternatively, similarly to the foregoing organic EL display panel 50a in accordance with the first embodiment, the through hole Ha may have another shape in a plan view, for example, like the through holes Hb, Hc, Hd, and Hf.

In addition, similarly to the foregoing organic EL display panel 50a in accordance with the first embodiment, the organic EL display panel 50e includes, in the non-display area N, an outer slit St provided annularly on the surface of the second resin substrate layer 8 that faces the TFT layer 30, so as to surround the plurality of slits Sa, Sb, Sc, Sd, and Se.

In addition, similarly to the foregoing organic EL display panel 50a in accordance with the first embodiment, the organic EL display panel 50e includes, in the non-display area N, an inner damming wall Wc provided annularly between the plurality of slits Sa, Sb, Sc, Sd, and Se and the outer slit St.

In addition, similarly to the foregoing organic EL display panel 50a in accordance with the first embodiment, the organic EL display panel 50e includes, in the non-display area N, a first bypass wiring line 16n and a second bypass wiring line 18n that bypass the through hole Ha around the outer slit St.

In addition, similarly to the foregoing organic EL display panel 50a in accordance with the first embodiment, the organic EL display panel 50e includes, in the frame area F: a first outer damming wall Wa provided outside a trench G so as to surround the display area D; and a second outer damming wall Wb provided around the first outer damming wall Wa.

In addition, similarly to the foregoing organic EL display panel 50a in accordance with the first embodiment, the organic EL display panel 50e includes, in the frame area F: a first frame line 18h provided inside the trench G; and a second frame line 18i provided outside the trench G.

In addition, similarly to the foregoing organic EL display panel 50a in accordance with the first embodiment, the organic EL display panel 50e includes, in the frame area F, a plurality of peripheral photo spacers 32b provided so as to protrude upward at both ends of the trench G.

Similarly to the foregoing organic EL display device 70 in accordance with the first embodiment, the organic EL display device including the above-described organic EL display panel 50e is flexible, displays images by causing the organic light-emitting layer 3 in the organic EL layer 33 in each subpixel P to emit light in a suitable manner via the first TFTs 9a, the second TFTs 9b, and the third TFTs 9c, and is structured to capture an image of an object in front of the organic EL display panel 50e by using the image sensor 60 installed on the rear of the organic EL display panel 50e.

The organic EL display device including the organic EL display panel 50e in accordance with the present embodiment can be manufactured by changing the pattern shape in partially removing the stacked film of the base coat film 11, the gate insulating film 13, the first interlayer insulating film 15, the second interlayer insulating film 17, and the third wiring layer from the non-display area N in the aforementioned organic EL element layer formation step in the method of manufacturing the organic EL display device 70 in accordance with the first embodiment.

As described above, in the organic EL display device including the organic EL display panel 50e in accordance with the present embodiment, the non-display area N is provided insularly inside the display area D along the panel edge E of the organic EL display panel 50e, the through hole Ha running through the organic EL display panel 50e in its thickness direction is provided in the non-display area N, and the plurality of annular banks R are provided so as to surround the through hole Ha. Here, the resin portion 8a of each bank R is divided by the plurality of slits Sa, Sb, Sc, Sd, and Se each formed annularly on the surface of the second resin substrate layer 8 that faces the TFT layer 30, so as to surround the through hole Ha. Then, the center of gravity (center) Ca of the through hole Ha in a plan view is located so as to be displaced in a direction further away from the panel edge E than the center of gravity (center) Cb of the slit Se in a plan view is displaced in that direction away from the panel edge E, the slit Se being the outermost slit in the plurality of slits Sa, Sb, Sc, Sd, and Se. This particular structure can further separate the through hole Ha from the panel edge E than in a case where the through hole (Ha) is concentric to the plurality of slits (Sa, Sb, Sc, Sd, and Se), thereby slowing down the penetration of moisture and like water content into the organic EL layer 33 on the panel edge E side of the through hole Ha, and can therefore restrain degradation of the organic EL layer 33 on the panel edge E side of the through hole Ha. Hence, in the organic EL display device including the organic EL display panel 50e including the plurality of banks R that use the resin substrate layer 10 around the through hole Ha, the structure can restrain degradation of the organic EL layer 33 on the panel edge E side of the through hole Ha, thereby improving the reliability of the organic EL display device.

### Other EmbodimentS

Each embodiment described above discussed, as an example, an organic EL layer with a five-layered structure including a hole injection layer, a hole transport layer, a light-emitting layer, an electron transport layer, and an electron injection layer. Alternatively, the organic EL layer may have, for example, a three-layered structure including, a hole injection and transport layer, a light-emitting layer, and an electron transport and injection layer.

In addition, each embodiment described above discussed, as an example, an organic EL display device in which the first electrode is an anode, and the second electrode is a cathode. The disclosure is equally applicable to an organic EL display device in which the organic EL layer has a reverse layered structure such that the first electrode is a cathode, and the second electrode is an anode.

In addition, each embodiment described above discussed, as an example, an organic EL display device in which one of the electrodes of a TFT that is connected to the first electrode is the drain electrode. The disclosure is equally applicable to an organic EL display device in which one of the electrodes of a TFT that is connected to the first electrode is termed the source electrode.

In addition, each embodiment described above described, as an example, an organic EL display device as the display device. The disclosure is applicable to a display device including a plurality of light-emitting elements, for example, applicable to a display device including QLEDs which are light-emitting elements that use a quantum-dot-containing layer.

### INDUSTRIAL APPLICABILITY

As described above, the disclosure is useful in flexible display devices.

1. A display device comprising a display panel including:
a resin substrate layer;
a thin film transistor layer provided on the resin substrate layer and including an inorganic insulating film;
a light-emitting element layer provided on the thin film transistor layer and including a plurality of first electrodes, a light-emitting functional layer, and a second electrode stacked sequentially correspondingly to a plurality of subpixels inside a display area; and
a first inorganic encapsulation film provided on the light-emitting element layer, wherein a non-display area is provided insularly inside the display area along a panel edge of the display panel,
a through hole running through the display panel in a thickness direction of the display panel is provided in the non-display area,
a plurality of banks are provided annularly in the non-display area so as to surround the through hole,
each of the plurality of banks includes: a resin portion formed of a part of the resin substrate layer; and an inorganic insulating layer provided on the resin portion and made of a same material, and provided in a same layer, as the inorganic insulating film,
the resin portion of each of the plurality of banks is divided by a plurality of slits each formed annularly on a surface of the resin substrate layer that faces the thin film transistor layer, so as to surround the through hole, and
the first inorganic encapsulation film is provided so as to cover the plurality of banks and the plurality of slits, wherein
the through hole has, in a plan view, a center of gravity that is located so as to be displaced in a direction further away from the panel edge than a center of gravity of one of the plurality of slits in a plan view is displaced in that direction away from the panel edge, the one of the plurality of slits being an outermost slit in the plurality of slits.

2. The display device according to claim 1, wherein in each of the plurality of banks, the inorganic insulating layer is provided so as to protrude like an eave from the resin portion toward either a through hole side or a display area side or both.

3. The display device according to claim 1- or 2, wherein the light-emitting functional layer and the second electrode are stacked on the inorganic insulating layer in each of the plurality of banks.

4. The display device according to claim 1, wherein an interval between the inorganic insulating layers in the plurality of banks and widths of these inorganic insulating layers are relatively large near the panel edge and relatively small opposite the panel edge.

5. The display device according to claim 4, wherein the interval between the inorganic insulating layers in the plurality of banks and the widths of these inorganic insulating layers are mutually equal near the panel edge and mutually equal opposite the panel edge.

6. The display device according to claim 4, wherein the interval between the inorganic insulating layers in the plurality of banks and the widths of these inorganic insulating layers are mutually different near the panel edge and mutually different opposite the panel edge.

7. The display device according to claim 6, wherein either the interval between the inorganic insulating layers in the plurality of banks or the widths of these inorganic insulating layers or both become(s) smaller when moving away from the through hole.

8. The display device according to claim 6, wherein either the interval between the inorganic insulating layers in the plurality of banks or the widths of these inorganic insulating layers or both become(s) larger when moving away from the through hole.

9. The display device according to claim 6, wherein either the interval between the inorganic insulating layers in the plurality of banks or the widths of these inorganic insulating layers or both become(s) smaller when moving away from the through hole near the panel edge and become(s) larger when moving away from the through hole opposite the panel edge.

10. The display device according to claim 6, wherein either the interval between the inorganic insulating layers in the plurality of banks or the widths of these inorganic insulating layers or both become(s) larger when moving away from the through hole near the panel edge and become(s) smaller when moving away from the through hole opposite the panel edge.

11. The display device according to claim 1, wherein the through hole and the plurality of slits are provided circularly in a plan view.

12. The display device according to claim 1, wherein
an organic encapsulation film is provided on the first inorganic encapsulation film,
an outer slit is provided in the non-display area on the surface of the resin substrate layer that faces the thin film transistor layer, so as to surround the plurality of slits,
the inorganic insulating film is divided by the outer slit and provided so as to protrude like an eave inside the outer slit, and
the outer slit is filled with the organic encapsulation film via the first inorganic encapsulation film.

13. The display device according to claim 12, wherein a damming wall is provided in contact with a peripheral portion of the organic encapsulation film via the first inorganic encapsulation film between the plurality of slits and the outer slit.

14. The display device according to claim 12, wherein
a second inorganic encapsulation film is provided on the first inorganic encapsulation film so as to cover the organic encapsulation film, and
a stacked film of the first inorganic encapsulation film and the second inorganic encapsulation film is provided so as to cover the plurality of banks and the plurality of slits.

15. The display device according to claim 1, wherein
the resin substrate layer includes: a first resin substrate layer provided opposite the thin film transistor layer; a second resin substrate layer provided near the thin film transistor layer; and an intra-substrate inorganic insulating film provided between the first resin substrate layer and the second resin substrate layer, and
the plurality of slits are provided on a surface of the second resin substrate layer that faces the thin film transistor layer.

16. The display device according to claim 1, wherein the through hole contains an electronic component installed in the through hole.

17. The display device according to claim 16, wherein the electronic component is an image sensor.

18. The display device according to claim 1, wherein the light-emitting functional layer is an organic electroluminescent layer.
